(19) United States
(12) Patent Application Publication
(10) Pub. No.: US 2021/0210542 A1
(43) Pub. Date: Jul. 8, 2021

(54) PHOTOELECTRIC SENSING INTEGRATED SYSTEM AND PACKAGING METHOD, LENS MODULE, AND ELECTRONIC DEVICE

(71) Applicant: Ningbo Semiconductor International Corporation, Ningbo (CN)

(72) Inventor: Xiaoshan QIN, Ningbo (CN)

(21) Appl. No.: 17/207,452

(22) Filed: Mar. 19, 2021

Related U.S. Application Data
(63) Continuation of application No. PCT/CN2019/106829, filed on Sep. 20, 2019.

(30) Foreign Application Priority Data
Sep. 21, 2018 (CN) 201811107586.6

(51) Int. Cl. H01L 27/146

(52) U.S. Cl. CPC H01L 27/14636; H01L 27/14627; H01L 27/14621; H01L 27/14634; H01L 27/1469; H01L 27/14618

(57) ABSTRACT

A photoelectric sensing integrated system and packaging method, a lens module, and an electronic device are provided. The packaging method includes: forming at least one photosensitive component, where a photosensitive component includes a photoelectric sensing chip and a light-transmitting cover plate oppositely disposed with the photoelectric sensing chip; providing a carrier substrate; bonding a CMOS peripheral chip, a capacitor and an interconnection pillar on the carrier substrate; forming an encapsulation layer on the carrier substrate, where the encapsulation layer at least fully fills space between the CMOS peripheral chip, the capacitor, and the interconnection pillar, and has at least one photoelectric sensing through-hole formed therein; placing at least the light-transmitting cover plate of the photosensitive component in a corresponding photoelectric sensing through-hole; and forming an interconnection structure to provide an electrical connection between the photoelectric sensing chip and each of the CMOS peripheral chip, the capacitor and the interconnection pillar.

### CROSS-REFERENCE TO RELATED APPLICATIONS

This application is a continuation application of PCT Patent Application No. PCT/CN2019/106829, filed on Sep. 20, 2019, which claims priority to Chinese patent application No. 201811107586.6, filed on Sep. 21, 2018, the entirety of all of which is incorporated herein by reference.

### FIELD OF THE DISCLOSURE

The present disclosure generally relates to the field of semiconductor manufacturing technology and, more particularly, relates to a photoelectric sensing integrated system and packaging method, a lens module, and an electronic device.

### BACKGROUND

With the continuous improvement of people's living standards, leisure life becomes richer, and photography has gradually become a common method to record travels and various daily lives. Therefore, electronic devices with a shooting function (e.g., a mobile phone, a tablet, a camera, etc.) have been widely used in people's daily life and work, and the electronic devices with a shooting function have gradually become indispensable and important tools.

An electronic device with a shooting function often has a lens module, and the design level of the lens module is one of important factors that determine the shooting quality. The lens module often includes a camera component with a photoelectric sensing chip and a lens component fixed above the camera component and configured to form an image of a to-be-shot subject. The photoelectric sensing chip is an electronic device that is capable of sensing externally incident light and converting the light into an electrical signal.

At present, to improve the imaging capability of the lens module, a corresponding photoelectric sensing chip with a substantially large imaging area is required, and circuit elements such as resistors, capacitors, and a peripheral chip are often arranged in the lens module. Therefore, the current packaging process requires that the photoelectric sensing chip, the circuit element and the peripheral chip are packaged and integrated with an electrical system. The disclosed photoelectric sensing integrated system and packaging method, the lens module, and the electronic device are directed to solve one or more problems set forth above and other problems in the art.

### BRIEF SUMMARY OF THE DISCLOSURE

One aspect of the present disclosure provides a packaging method of a photoelectric sensing integrated system. The packaging method includes forming at least one photosensitive component. A photosensitive component of the at least one photosensitive component includes a photoelectric sensing chip and a light-transmitting cover plate oppositely disposed with the photoelectric sensing chip, and the light-transmitting cover plate is attached to the photoelectric sensing chip. The packaging method also includes providing a carrier substrate, and bonding a CMOS peripheral chip, a capacitor and an interconnection pillar on the carrier substrate. In addition, the packaging method includes forming an encapsulation layer on the carrier substrate. The encapsulation layer at least fully fills space between the CMOS peripheral chip, the capacitor, and the interconnection pillar, and at least one photoelectric sensing through-hole is formed in the encapsulation layer. Moreover, the packaging method includes placing at least the light-transmitting cover plate of the photosensitive component in a corresponding photoelectric sensing through-hole of the at least one photoelectric sensing through-hole. Further, the method includes forming an interconnection structure to provide an electrical connection between the photoelectric sensing chip and each of the CMOS peripheral chip, the capacitor and the interconnection pillar.

Another aspect of the present disclosure provides a photoelectric sensing integrated system. The photoelectric sensing integrated system includes a CMOS peripheral chip, a capacitor, an interconnection pillar, an encapsulation layer, at least one photosensitive component, and an interconnection structure. The encapsulation layer covers at least sidewalls of the CMOS peripheral chip, the capacitor, and the interconnection pillar and has at least one photoelectric sensing through-hole formed therein. A photosensitive component of the at least one photosensitive component includes a photoelectric sensing chip and a light-transmitting cover plate oppositely disposed with the photoelectric sensing chip, and the light-transmitting cover plate is attached to the photoelectric sensing chip. At least the light-transmitting cover plate of the photosensitive component is placed in a corresponding photoelectric sensing through-hole of the at least one photoelectric sensing through-hole. The interconnection structure is configured to provide an electrical connection between the photoelectric sensing chip and each of the CMOS peripheral chip, the capacitor and the interconnection pillar.

Another aspect of the present disclosure provides a lens module. The lens module includes a photoelectric sensing integrated system. The photoelectric sensing integrated system includes a CMOS peripheral chip, a capacitor, an interconnection pillar, an encapsulation layer, at least one photosensitive component, and an interconnection structure. The encapsulation layer covers at least sidewalls of the CMOS peripheral chip, the capacitor, and the interconnection pillar and has at least one photoelectric sensing through-hole formed therein. A photosensitive component of the at least one photosensitive component includes a photoelectric sensing chip and a light-transmitting cover plate oppositely disposed with the photoelectric sensing chip, and the light-transmitting cover plate is attached to the photoelectric sensing chip. At least the light-transmitting cover plate of the photosensitive component is placed in a corresponding photoelectric sensing through-hole of the at least one photoelectric sensing through-hole. The interconnection structure is configured to provide an electrical connection between the photoelectric sensing chip and each of the CMOS peripheral chip, the capacitor and the interconnection pillar. The lens module also includes a lens component electrically connected with the interconnection pillar or the interconnection structure.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIGS. 1-9 illustrate schematic diagrams of semiconductor structures corresponding to certain stages of an exemplary packaging method of a photoelectric sensing integrated system consistent with various disclosed embodiments of the present disclosure;

FIGS. 10-11 illustrate schematic diagrams of semiconductor structures corresponding to certain stages of another exemplary packaging method of a photoelectric sensing integrated system consistent with various disclosed embodiments of the present disclosure;

FIGS. 12-17 illustrate schematic diagrams of semiconductor structures corresponding to certain stages of another exemplary packaging method of a photoelectric sensing integrated system consistent with various disclosed embodiments of the present disclosure;

FIG. 18 illustrates a schematic diagram of a semiconductor structure corresponding to certain stages of another exemplary packaging method of a photoelectric sensing integrated system consistent with various disclosed embodiments of the present disclosure;

FIGS. 19-23 illustrate schematic diagrams of semiconductor structures corresponding to certain stages of another exemplary packaging method of a photoelectric sensing integrated system consistent with various disclosed embodiments of the present disclosure;

FIG. 24 illustrates a schematic diagram of a semiconductor structure corresponding to certain stages of another exemplary packaging method of a photoelectric sensing integrated system consistent with various disclosed embodiments of the present disclosure; and

FIGS. 25-27 illustrate schematic diagrams of semiconductor structures corresponding to certain stages of another exemplary packaging method of a photoelectric sensing integrated system consistent with various disclosed embodiments of the present disclosure

### DETAILED DESCRIPTION

Reference will now be made in detail to exemplary embodiments of the disclosure, which are illustrated in the accompanying drawings. However, those skilled in the art may easily understand that the present disclosure may be implemented without one or more of these details. In certain examples, some well-known technical features in the art are not described herein to avoid confusion with the present disclosure. Wherever possible, the same reference numbers will be used throughout the drawings to refer to the same or the alike parts.

The lens module is equipped with a photoelectric sensing chip, a circuit element such as a capacitor, and a peripheral chip. To achieve the integration and electrical connection of the photoelectric sensing chip, the capacitor, and the peripheral chip, the photoelectric sensing chip, the capacitor, and the peripheral chip are often need to be attached on a circuit board, respectively, and the photoelectric sensing chip, the capacitor and the peripheral chip are electrically connected with the circuit board through leads.

Therefore, the current packaging process is substantially complicated, and the process cost is high. Due to the arrangement of the circuit board, it is difficult to reduce the thickness of the formed lens module.

The present disclosure provides a packaging method of a photoelectric sensing integrated system. The method may include forming at least one photosensitive component. A photosensitive component may include a photoelectric sensing chip and a light-transmitting cover plate oppositely disposed with the photoelectric sensing chip, and the light-transmitting cover plate is attached to the photoelectric sensing chip. The method may also include providing a carrier substrate, and bonding a CMOS peripheral chip, a capacitor and an interconnection pillar on the carrier substrate. In addition, the method may include forming an encapsulation layer on the carrier substrate, where the encapsulation layer may at least fully fill the space between the CMOS peripheral chip, the capacitor, and the interconnection pillar, and at least one photoelectric sensing through-hole may be formed in the encapsulation layer. Moreover, the method may include placing at least the light-transmitting cover plate of the photosensitive component in a corresponding photoelectric sensing through-hole. Further, the method may include forming an interconnection structure to provide an electrical connection between the photoelectric sensing chip and each of the CMOS peripheral chip, the capacitor, and the interconnection pillar.

In the present disclosure, the CMOS peripheral chip, capacitor and interconnection pillar may be integrated in the encapsulation layer, and at least one photoelectric sensing through-hole may be formed in the encapsulation layer. At least the light-transmitting cover plate of the photosensitive component may be placed in the corresponding photoelectric sensing through-hole, and an interconnection structure may be formed to achieve the electrical connection between the photoelectric sensing chip and each of the CMOS peripheral chip, the capacitor and the interconnection pillar. Compared with the scheme where the photoelectric sensing chip, the CMOS peripheral chip and the capacitor are attached on the circuit board, the present disclosure may omit the circuit board, which may not only simplify the process steps for achieving electrical connection, but also facilitate to improve packaging efficiency, to reduce the cost of electrical connection process, and to effectively reduce the total thickness of the subsequently formed lens module. Moreover, the photosensitive component may be made separately, and the process of integrating the CMOS peripheral chip, capacitor and interconnection pillar into the encapsulation layer may be carried out separately. Accordingly, the manufacturing process of the photosensitive component may be prevented from affecting the integration of the CMOS peripheral chip, capacitor, and interconnection pillar. Similarly, the integration of the CMOS peripheral chip, capacitor, and interconnection pillar may be prevented from affecting the photosensitive component, thereby facilitating to improve the packaging reliability and to reduce processing cost.

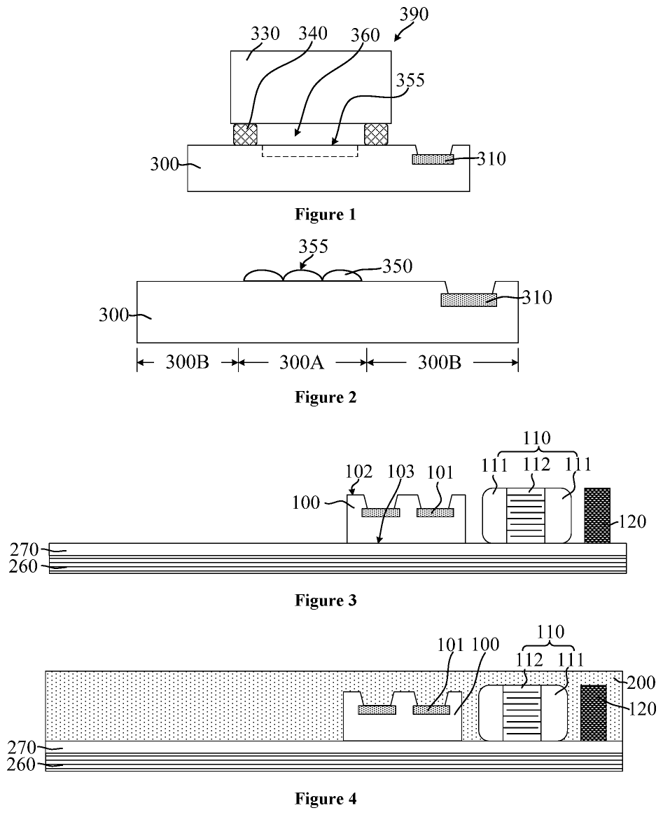

FIGS. 1-9 illustrate schematic diagrams of semiconductor structures corresponding to certain stages of a packaging method of a photoelectric sensing integrated system consistent with various disclosed embodiments of the present disclosure.

FIG. 2 illustrates an enlarged view of a photoelectric sensing chip in FIG. 1. Referring to FIG. 1 and FIG. 2, at least one photosensitive component 390 (illustrated in FIG. 1) may be formed. The photosensitive component 390 may include a photoelectric sensing chip 300 (illustrated in FIG. 1) and a light-transmitting cover plate 330 (illustrated in FIG. 1) oppositely disposed with the photoelectric sensing chip 300. The light-transmitting cover plate 330 may be attached to the photoelectric sensing chip 300.

A lens module may often include a camera component and a lens component fixed above the camera component and configured to form an image of a to-be-shot subject. The photosensitive component 390 may be used as the camera component of the lens module.

In one embodiment, the photoelectric sensing chip 300 may be an image sensor chip. The image sensor may be a semiconductor device that is capable of converting an optical image into electrical signals.

In one embodiment, the photoelectric sensing chip 300 may be a CMOS image sensor (CIS) chip. In another embodiment, the photoelectric sensing chip may be a charge coupled device (CCD) image sensor chip.

Referring to FIG. 2, the photoelectric sensing chip 300 may include a photoelectric sensing region 300A and a peripheral region 300B surrounding the photoelectric sensing region 300A. The photoelectric sensing chip 300 may include a light-signal-receiving-surface 355 located in the photoelectric sensing region 300A. The photoelectric sensing chip 300 may receive and sense a light radiation signal through the light-signal-receiving-surface 355.

Specifically, the light-signal-receiving-surface 355 may face the light-transmitting cover plate 330, thereby preventing the subsequent packaging process from polluting the imaging region of the photoelectric sensing chip 300 (i.e., the photoelectric sensing region 300A) and from affecting the performance of the photoelectric sensing chip 300, and improving the imaging quality of the subsequently formed lens module.

It should be noted that the photoelectric sensing chip 300 may include a plurality of pixel units, e.g., a red pixel unit, a green pixel unit, and a blue pixel unit. Therefore, the photoelectric sensing chip 300 may include a plurality of semiconductor photosensitive devices (not illustrated), a plurality of filter films (not illustrated) on the plurality of semiconductor photosensitive devices, and a micro-lens 350 (referring to FIG. 2) on the filter film. A top surface of the micro lens 350 may be the light-signal-receiving-surface 355.

It should be noted that the photoelectric sensing chip 300 may further include a first chip bonding pad 310 disposed in the peripheral region 300B for achieving electrical connection between the photoelectric sensing chip 300 and any other circuit.

In one embodiment, the first chip bonding pad 310 may face toward the light-transmitting cover plate 330. In another embodiment, according to actual process requirements, the first chip bonding pad may face away from the light-transmitting cover plate.

Therefore, to achieve the electrical connection between the photoelectric sensing chip 300 and any other circuit, the light-transmitting cover plate 330 may cover the photoelectric sensing region 300A and may expose the first chip bonding pad 310. To ensure the normal performance of the photoelectric sensing chip 300, the light-transmitting cover plate 330 may be an infrared filter glass sheet or a fully light-transmitting glass sheet.

In one embodiment, the light-transmitting cover plate 330 may be an infrared filter glass sheet. When the lens module is in operation, the light-transmitting cover plate 330 may eliminate the influence of infrared light in the incident light on the performance of the photoelectric sensing chip 300, and may prevent the photoelectric sensing chip 300 from having problems such as color shift, which may facilitate to improve the image resolution and color reproduction, and correspondingly may improve the imaging effect of the lens module.

Specifically, the infrared filter glass sheet may be a blue glass infrared cut filter (IRCF). The blue glass infrared cut filter may have the characteristic of absorbing infrared light, and may avoid the interference of reflected light, thereby preventing the problems of bright spots and ghost images caused by multiple reflections of light. Therefore, while filtering infrared light, the blue glass infrared cut filter may facilitate to further improve the imaging effect of the lens module. In another embodiment, the infrared filter glass sheet may include a glass sheet and an infrared cut coating on the surface of the glass, where the infrared cut coating may filter out infrared light using the reflection principle.

It should be noted that the subsequent manufacturing process may further include forming an encapsulation layer at least covering the sidewalls of the CMOS peripheral chip, capacitor and the interconnection pillar. A photoelectric sensing through-hole may be formed in the encapsulation layer, and at least the light-transmitting cover plate 330 of the photosensitive component 390 may be placed in the corresponding photoelectric sensing through-hole, such that the thickness of the light-transmitting cover plate 330 may be compatible with the thickness of the CMOS peripheral chip, the thickness of the capacitor, and the height of the interconnection pillar. In addition, considering the optical performance of the photosensitive component 390 and the thickness of the lens module, the thickness of the light-transmitting cover plate 330 may not be too small or too large.

In one embodiment, according to actual process requirements, the thickness of the light-transmitting cover plate 330 may be in a range of approximately 100 μm-300 μm, e.g., 150 μm, 200 μm, or 250 μm.

In one embodiment, the light-transmitting cover plate 330 may be attached to the photoelectric sensing chip 300 by an adhesive structure 340 (referring to FIG. 1) disposed therebetween. The adhesive structure 340 may surround the light-signal-receiving-surface 355.

The adhesive structure 340 may be configured to achieve the physical connection between the photoelectric sensing chip 300 and the light-transmitting cover plate 330. Moreover, the light-transmitting cover plate 330, the adhesive structure 340 and the photoelectric sensing chip 300 may enclose a cavity 360 (referring to FIG. 1), to prevent the light-transmitting cover plate 330 from being in direct contact with the photoelectric sensing chip 300, and to prevent the light-transmitting cover plate 330 from affecting the optical performance of the photoelectric sensing chip 300.

In one embodiment, the adhesive structure 340 may surround the light-signal-receiving-surface 355, such that the light-transmitting cover plate 330 above the light-signal-receiving-surface 355 may be located on the photosensitive path of the photoelectric sensing chip 300, and, thus, ensuring the optical performance of the photoelectric sensing chip 300.

Specifically, forming the photosensitive component 390 may include: forming the annular adhesive structure 340 on the edge region (not labeled) of the light-transmitting cover plate 330; making the light-signal-receiving-surface 355 face the adhesive structure 340; and bonding the peripheral region 300B on the adhesive structure 340 to make the light-transmitting cover plate 330 be attached to the photoelectric sensing chip 300.

In one embodiment, the adhesive structure 340 may be made of a photolithographable dry film. The photolithographable dry film may be adhesive and photolithographable, and, thus, while achieving the physical connection between the photoelectric sensing chip 300 and the light-transmitting cover plate 330, may facilitate to reduce the process difficulty of forming the adhesive structure 340. In another embodiment, the adhesive structure may be made of photolithographable polyimide, photolithographable polybenzoxazole (PBO), or photolithographable benzocyclobutene (BCB).

In one embodiment, for illustrative purposes, a quantity of the photosensitive elements 390 may be one as an example. In another embodiment, according to the quantity of lens components in the lens module, the quantity of the photosensitive components may be more than one. For example, when the lens module is a dual-camera lens module, correspondingly, the quantity of the photosensitive components may be two.

Referring to FIG. 3, a carrier substrate 260 may be provided, and the CMOS peripheral chip 100, the capacitor 110, and the interconnection pillar 120 may be bonded on the carrier substrate 260.

The carrier substrate 260 may be configured to provide a process platform for subsequently integrating and electrically connecting the CMOS peripheral chip 100, the capacitor 110, and the interconnection pillar 120, thereby improving the process operability of the subsequent process.

In one embodiment, the CMOS peripheral chip 100, capacitor 110, and interconnection pillar 120 may be bonded on the carrier substrate 260 by a temporary bonding (TB) method, to facilitate subsequent removal of the carrier substrate 260.

Specifically, the carrier substrate 260 may be a carrier wafer. In another embodiment, the carrier substrate may be any other type of substrate.

In one embodiment, the CMOS peripheral chip 100, the capacitor 110 and the interconnection pillar 120 may be temporarily bonded on the carrier substrate 260 through an adhesive layer 270. The adhesive layer 270 may further be used as a peeling layer to facilitate the separation of the CMOS peripheral chip 100, the capacitor 110, and the interconnection pillar 120 from the carrier substrate 260.

In one embodiment, the adhesive layer 270 may be a foamed film. The foamed film may include a micro-adhesive surface and a foamed surface that are opposite to each other. The foamed film may be sticky at room temperature, after the foamed surface is attached to the carrier substrate 260, the foamed surface may lose viscosity by subsequently heating the foamed film, to achieve the separation of the CMOS peripheral chip 100, the capacitor 110, and the interconnection pillar 120 from the carrier substrate 260.

In another embodiment, the adhesive layer may be a die attach film (DAF). The die attach film may be an ultra-thin film adhesive used to connect a semiconductor chip and a packaging substrate, a chip and another chip in the semiconductor packaging process, which may have a substantially high reliability and convenience, and may facilitate the realization of stacking and thinning of semiconductor packaging.

In another embodiment, the CMOS peripheral chip, capacitor, and interconnection pillar may be temporarily bonded on the carrier substrate by electrostatic bonding.

The capacitor 110 may be a kind of passive components, which may be configured to achieve electrical connection with the photoelectric sensing chip 300 (referring to FIG. 1), and may facilitate the photosensitive operation of the photoelectric sensing chip 300.

Therefore, the capacitor 110 may include an electrode 111, and the electrode 111 may be configured to achieve an electrical connection between the capacitor 110 and any other circuit.

In one embodiment, the capacitor 110 may be a ceramic capacitor. The ceramic capacitor may be a general term for capacitors with ceramic material as the medium. Compared with other capacitors, the ceramic capacitor may have advantages such as high operating temperature, large specific capacity, desired moisture resistance, low dielectric loss, and a wide range of capacitance temperature coefficients, and may have great prospects in electronic circuits.

Specifically, the capacitor 110 may be a multilayer ceramic capacitor (MLCC). The multilayer ceramic capacitor may be formed by: laminating ceramic dielectric membranes with printed electrodes (i.e., internal electrodes) in a staggered manner, forming a ceramic chip by one-time high-temperature sintering, and sealing the two ends of the ceramic chip with metal layers, where the metal layer may be used as the electrode 111 of the multilayer ceramic capacitor.

The multilayer ceramic capacitor may not only have the general characteristic “isolating direct current (DC) and passing alternating current (AC)” of capacitive elements, but also may have the advantages such as small size, large specific capacitance, long life, high reliability, and easy implementation of surface mount, to meet the demand for miniaturization, low cost, and large-capacity technology development of capacitive elements.

Correspondingly, the capacitor 110 may include a ceramic body 112 with internal electrodes (not labeled), and electrodes 111 located on both ends of the ceramic body 112.

It should be noted that when the capacitor 110 is a multilayer ceramic capacitor, the thickness of the multilayer ceramic capacitor may be dependent on the quantity of layers of the ceramic dielectric film. The larger the quantity of layers of the ceramic dielectric film, the larger the thickness of the multilayer ceramic capacitor.

In one embodiment, the thickness of the multilayer ceramic capacitor may be in a range of approximately 100 μm-400 μm, e.g., 150 μm, 200 μm, 250 μm, 300 μm, or 350 μm. According to the performance requirements of the capacitor 110, the multilayer ceramic capacitor with a suitable thickness may be selected.

The CMOS peripheral chip 100 may be another active element with specific functions in the camera component in addition to the photoelectric sensing chip 300. After subsequently being electrically connected with the photoelectric sensing chip 300, the CMOS peripheral chip 100 may be configured to provide a peripheral circuit, e.g., analog power supply circuit and digital power supply circuit, voltage buffer circuit, shutter circuit, shutter driving circuit, etc., for the photoelectric sensing chip 300.

The CMOS peripheral chip 100 may include a second chip bonding pad 101 for achieving electrical connection between the CMOS peripheral chip 100 and any other circuit.

The CMOS peripheral chip 100 may be made using integrated circuit manufacturing technology. Therefore, the CMOS peripheral chip 100 may often not only include devices such as NMOS devices, PMOS devices formed on a substrate, but also include an interlayer dielectric layer, a metal interconnection structure, and a bonding pad, etc.

In one embodiment, a surface of the CMOS peripheral chip 100 that exposes the second chip bonding pad 101 may be a front surface 102 of the chip, and a surface opposite to the front surface 102 of the chip may be a back surface 103 of the chip. The back surface 103 of the chip may refer to a bottom surface of the substrate on a side of the CMOS peripheral chip 100 facing away from the second chip bonding pad 101.

In certain embodiments, according to actual process conditions, the second chip bonding pad may be located on the back surface of the chip.

It should be noted that to reduce the process difficulty of the subsequent electrical connection between the CMOS peripheral chip 100, the capacitor 110 and the interconnection pillar 120, the thickness difference between the CMOS peripheral chip 100 and the capacitor 110 may not be too large or too small. Therefore, in one embodiment, the thickness of the CMOS peripheral chip 100 may be in a range of approximately 100 μm-300 μm, e.g., 150 μm, 200 μm, or 250 μm.

Specifically, the back surface 103 of the chip of the CMOS peripheral chip 100 may be thinned, to make the thickness of the CMOS peripheral chip 100 meet the process requirements. In practical applications, the thickness of the CMOS peripheral chip 100 may be reasonably set according to the thickness of the CMOS peripheral chip 100 before the thinning process and the achievability of the process.

It should be noted that in one embodiment, the surface of the CMOS peripheral chip 100 facing away from the carrier substrate 260 may be lower than the surface of the capacitor 110 facing away from the carrier substrate 260. In another embodiment, the surface of the CMOS peripheral chip facing away from the carrier substrate may be coplanar with the surface of the capacitor facing away from the carrier substrate.

The interconnection pillar 120 may be configured to be electrically connected with a voice coil motor holder (VCM) in the lens component.

In one embodiment, along an extension direction of the interconnection pillar 120, the interconnection pillar 120 may have opposite ends. One end of the interconnection pillar 120 may be configured to be electrically connected with the lens component of the lens module, and the other end of the interconnection pillar 120 may be configured to be electrically connected with the photoelectric sensing chip 300, the capacitor 110, and the CMOS peripheral chip 100. Therefore, the photoelectric sensing chip 300, the capacitor 110, and the CMOS peripheral chip 100 may be electrically connected with the lens component, thereby achieving the circuit conduction of the lens module.

The interconnection pillar 120 may have a columnar shape, and may have a certain height along the extension direction. In other words, after the encapsulation layer is subsequently formed, the interconnection pillar 120 may be embedded in the encapsulation layer and may be extended along a thickness direction of the encapsulation layer, which may facilitate the electrical connection between the photoelectric sensing chip 300, the capacitor 110 and the CMOS peripheral chip 100 with the lens component through the interconnection pillar 120.

Correspondingly, the interconnection pillar 120 may be made of a conductive material. In one embodiment, the interconnection pillar 120 may be made of a metal (e.g., copper) or a doped semiconductor with a certain resistance requirement. The interconnection pillar 120 made of such material may have desired conductivity and resistance controllability, such that the electrical characteristics of the interconnection pillar 120 may meet the process requirements. Further, the interconnection pillar 120 made of such material may be prefabricated, such that the morphology and size of the interconnection pillar 120 may meet the process requirements.

To reduce the process difficulty of subsequently achieving electrical connection between the CMOS peripheral chip 100, the capacitor 110 and the interconnection pillar 120, the difference between the height of the interconnection pillar 120 and the thickness of the capacitor 110 may not be too large or too small. Therefore, in one embodiment, the height of the interconnection pillar 120 may be in a range of approximately 100 μm-400 μm, e.g., 150 μm, 200 μm, 250 μm, 300 μm, or 350 μm.

It should be noted that the interconnection pillar 120 may be easily manufactured. Therefore, in practical applications, the height of the interconnection pillar 120 may be equal to the thickness of the capacitor 110.

It should be noted that in certain embodiments, the surface of the CMOS peripheral chip facing away from the carrier substrate, the surface of the multilayer ceramic capacitor facing away from the carrier substrate, and the surface of the interconnection pillar facing away from the carrier substrate may be coplanar.

In one embodiment, bonding the CMOS peripheral chip 100, the capacitor 110, and the interconnection pillar 120 on the carrier substrate 260 may include temporarily bonding the surface of the CMOS peripheral chip 100 facing away from the second chip bonding pad 101, any surface of the ceramic body 112 along a stacking direction of the internal electrodes (not labeled), and any end of the interconnection pillar 120 on the carrier substrate 260.

Referring to FIGS. 4-8, an encapsulation layer 200 may be formed over the carrier substrate 260, to at least fully fill the space between the CMOS peripheral chip 100, the capacitor 110 and the interconnection pillar 120. At least one photoelectric sensing through-hole 250 (illustrated in FIG. 7) may be formed in the encapsulation layer 200. At least the light-transmitting cover plate 330 (illustrated in FIG. 1) of the photosensitive component 390 may be placed in a corresponding photoelectric sensing through-hole 250. An interconnection structure 210 (referring to FIG. 7) may be formed to provide an electrical connection between the photoelectric sensing chip 300 (referring to FIG. 8) and each of the CMOS peripheral chip 100, capacitor 110 and the interconnection pillar 120.

The encapsulation layer 200 may fix the CMOS peripheral chip 100, the capacitor 110, and the interconnection pillar 120, such that package integration of the CMOS peripheral chip 100, the capacitor 110, and the interconnection pillar 120 may be achieved. Through the interconnection structure 210, the electrical integration between the CMOS peripheral chip 100, the capacitor 110, the interconnection pillar 120 and the photoelectric sensing chip 300 may be achieved. Compared with the scheme where the photoelectric sensing chip, the CMOS peripheral chip and the capacitor are packaged on the circuit board, the present disclosure may omit the circuit board, which may not only simplify the process steps for achieving electrical connection, but also facilitate to improve packaging efficiency, to reduce the cost of electrical connection process, and to effectively reduce the total thickness of the subsequently formed lens module.

Therefore, after the encapsulation layer 200 is formed, the encapsulation layer 200 may at least fully fill the space between the CMOS peripheral chip 100, the capacitor 110, and the interconnection pillar 120.

Referring to FIG. 4, in one embodiment, to improve the flatness of the encapsulation layer 200 to facilitate subsequent electrical connection process, the encapsulation layer 200 may cover the CMOS peripheral chip 100, the capacitor 110, and the interconnection pillar 120. A top of the encapsulation layer 200 may be above the CMOS peripheral chip 100, the capacitor 110 and the interconnection pillar 120.

The encapsulation layer 200 may have functions such as insulation, sealing and moisture-proof, and may reduce the probability of the CMOS peripheral chip 100, the capacitor 110 and the interconnection pillar 120 being damaged, contaminated or oxidized, thereby facilitating to improve the performance and reliability of the formed lens module.

In one embodiment, forming the encapsulation layer 200 may include a molding process, and correspondingly, the encapsulation layer 200 may be a molding layer.

In one embodiment, the encapsulation layer 200 may be made of epoxy resin. Epoxy resin may have advantages such as low shrinkage, desired adhesion, desired corrosion resistance, desired electrical properties and low cost, and may be widely used as packaging materials for electronic devices and integrated circuits.

A thickness of the encapsulation layer 200 (not labeled) may need to be determined according to the thickness of the CMOS peripheral chip 100, the thickness of the capacitor 110, the height of the interconnection pillar 120, and actual process requirements, such that the encapsulation layer 200 may at least fully fill the space between the CMOS peripheral chip 100, the capacitor 110 and the interconnection pillar 120.

The photoelectric sensing through-hole 250 may be configured to accommodate at least the light-transmitting cover plate 330 of the photosensitive component 390, to achieve the package integration of the photosensitive component 390, the CMOS peripheral chip 100, the capacitor 110 and the interconnection pillar 120.

In one embodiment, the photoelectric sensing through-hole 250 may be merely configured to accommodate the light-transmitting cover plate 330. In other words, after the light-transmitting cover plate 330 is placed in the corresponding photoelectric sensing through-hole 250, the photoelectric sensing chip 300 may be located outside the photoelectric sensing through-hole 250.

The interconnection structure 210 may be electrically connected with the second chip bonding pad 101 of the CMOS peripheral chip 100, the electrode 111 of the capacitor 110, and the end of the interconnection pillar 120 facing away from the carrier substrate 260. After the light-transmitting cover plate 330 is placed in the corresponding photoelectric sensing through-hole 250, the interconnection structure 210 may be further electrically connected with the first chip bonding pad 310 of the photoelectric sensing chip 300, thereby providing an electrical connection between the photoelectric sensing chip 300 and each of the CMOS peripheral chip 100, the capacitor 110 and the interconnection pillar 120.

In one embodiment, to improve process feasibility and reduce process complexity, after forming the interconnection structure 210, the photoelectric sensing through-hole 250 may be formed.

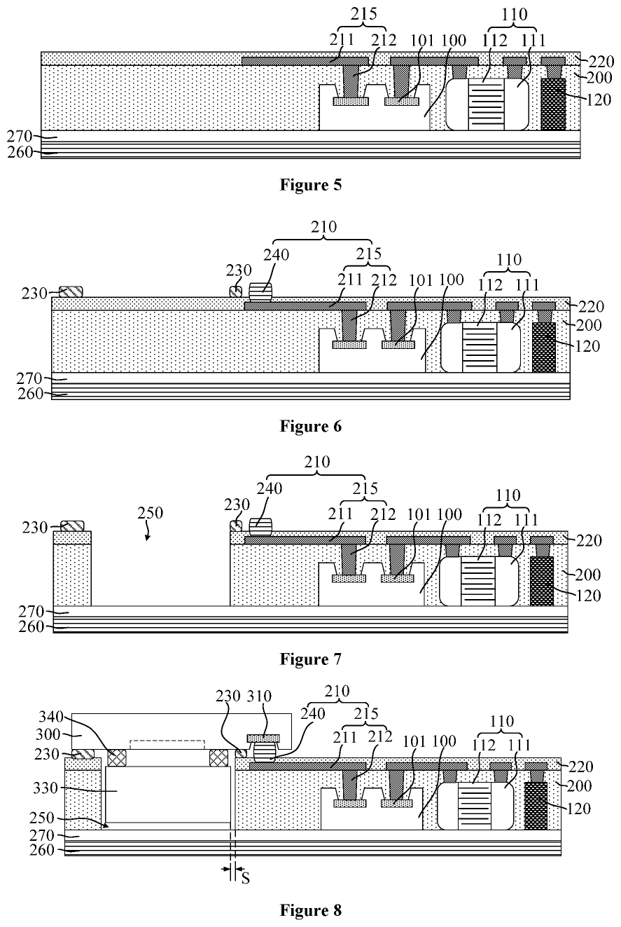

Referring to FIG. 5, forming the interconnection structure 210 may include forming a rewiring structure 215 on the surface of the encapsulation layer 200 facing away from the carrier substrate 260 for electrically connecting the second chip bonding pad 101, the electrode 111 of the capacitor 110, and the interconnection pillar 120.

The rewiring structure 215 may be configured to achieve the electrical connection between the CMOS peripheral chip 100, the capacitor 110 and the interconnection pillar 120.

In one embodiment, because the encapsulation layer 200 covers the CMOS peripheral chip 100, the capacitor 110, and the interconnection pillar 120, the rewiring structure 215 may include: a conductive pillar 212 located in the encapsulation layer 200 and connected with the second chip bonding pad 101, the electrode 111 and the end of the interconnection pillar 120 facing away from the carrier substrate 260, respectively; and the interconnection layer 211 located on the surface of the encapsulation layer 200 facing away from the carrier substrate 260 and connected with the plurality of conductive pillars 212.

The rewiring structure 215 may facilitate to reduce the distance between the CMOS peripheral chip 100, the capacitor 110 and the interconnection pillar 120, thereby facilitating the reduction of the size of the lens module. The thickness of the interconnection layer 211 may often be small, thereby facilitating to reduce the thickness of the lens module.

Specifically, forming the conductive pillar 212 may include: forming a plurality of conductive holes (not illustrated) from the surface of the encapsulation layer 200 facing away from the carrier substrate 260, where the plurality of conductive holes may expose the second chip bonding pad 101 of the CMOS peripheral chip 100, the electrode 111 of the capacitor 110, and the end of the interconnection pillar 120 facing away from the carrier substrate 260, respectively; and filling the conductive hole with a conductive material to form the plurality of conductive pillars 212 electrically connected with the second chip bonding pad 101, the electrode 111 and the interconnection pillar 120.

In one embodiment, an electroplating process may be used to fill the conductive holes with a conductive material, and the conductive material may cover the surface of the encapsulation layer 200. The conductive material may be planarized to remove a portion of the conductive material above the encapsulation layer 200. The conductive material in the conductive hole may be retained to form the conductive pillar 212.

In one embodiment, the conductive material may be copper. In other words, the conductive pillar 212 may be a Cu pillar. The resistivity of copper may be substantially low. By selecting the copper material, the conductivity of the conductive pillar 212 may be improved. The filling of copper may be desired, which may facilitate to improve the filling effect of the conductive material in the conductive hole, thereby improving the formation quality of the conductive pillar 212 in the conductive hole. In certain embodiments, the conductive pillar may be made of any other applicable conductive material.

In one embodiment, the interconnection layer 211 may serve as a redistribution layer (RDL). The interconnection layer 211 may be electrically connected with the second chip bonding pad 101, the electrode 111, and the interconnection pillar 120 through the plurality of conductive pillars 212, and may be configured to redistribute the second chip bonding pad 101, the electrode 111, and the end of the interconnection pillar 120 facing away from the carrier substrate 260, to achieve the electrical connection between the CMOS peripheral chip 100, the capacitor 110, the interconnection pillar 120 and any other circuit.

In one embodiment, the interconnection layer 211 may be made of aluminum. The aluminum process may be substantially simple and the process cost may be substantially low. Therefore, the selection of the aluminum interconnection layer may facilitate to reduce the process difficulty and process cost of the packaging process. In certain embodiments, the interconnection layer may be made of any other applicable conductive material.

Specifically, forming the interconnection layer 211 may include: forming an interconnection material layer on the surface of the encapsulation layer 200 facing away from the carrier substrate 260, where the interconnection material layer may cover the conductive pillar 212; and patterning the interconnection material layer to form the interconnection layer 211 connected with the plurality of conductive pillars 212.

It should be noted that in one embodiment, the plurality of conductive pillars 212 may be formed in a same process step, and the interconnection layer 211 may also be formed in a same process step. Therefore, the rewiring structure 215 may electrically connect the CMOS peripheral chip 100, the capacitor 110, and the interconnection pillar 120, and correspondingly, may facilitate to reduce the cost of the electrical connection process, to simplify the process steps of the electrical connection process, and to improve packaging efficiency.

Referring to FIG. 6, forming the interconnection structure 210 may further include forming a first conductive bump 240 on the rewiring structure 215, for electrically connecting with the first chip bonding pad 310 of the photoelectric sensing chip 300 (referring to FIG. 1). The first conductive bump 240 and the rewiring structure 215 may form the interconnection structure 210.

The first conductive bump 240 may be electrically connected with the rewiring structure 215, and the first conductive bump 240 may be configured to be electrically connected with the first chip bonding pad 310, to achieve electrical connection between the photoelectric sensing chip 300, the CMOS peripheral chip 100, the capacitor 110 and the interconnection pillar 120. Moreover, through the first conductive bump 240, a physical connection between the photosensitive component 390 and the encapsulation layer 200 may be achieved.

In one embodiment, the first conductive bump 240 may be formed by a bumping process. In other words, the first conductive bump 240 may be a bump. Compared with a scheme using ball-placing process, the bumping process may facilitate to reduce the thickness of the first conductive bump 240, thereby reducing the thickness of the subsequently formed lens module.

Specifically, in the step of forming the first conductive bump 240, according to a preset position of the photoelectric sensing through-hole 250 (referring to FIG. 7) subsequently formed in the encapsulation layer 200, the first conductive bump 240 may be formed on the surface of the interconnection layer 211 at the predetermined position.

Referring to FIG. 6, it should be noted that after forming the rewiring structure 215 and before forming the first conductive bump 240, the method may further include forming a passivation layer 220 on the encapsulation layer 200 to cover the interconnection layer 211.

The passivation layer 220 may be configured to insulate the interconnection layers 211, and may be configured to provide a process platform for the formation of the first conductive bump 240. In addition, the passivation layer 220 may have functions such as waterproof, anti-oxidation and anti-pollution.

In one embodiment, the passivation layer 220 may be made of a photosensitive material. Correspondingly, the passivation layer 220 may be formed through a photolithography process, which may facilitate to simplify the process steps and reduce the process cost.

In one embodiment, the passivation layer 220 may be made of a photosensitive polymer material. The polymer material may have a substantially low dielectric constant and a substantially small loss tangent value.

Specifically, the passivation layer 220 may be made of photosensitive polyimide (PI), photosensitive benzocyclobutene (BCB), photosensitive polybenzoxazole (PBO), or a combination thereof.

The passivation layer 220 made of such material may have low moisture absorption and high glass transition temperature, which may meet the process requirements. Moreover, in the process of forming the passivation layer 220, the passivation layer 220 may have desired leveling property, which may facilitate to improve the surface flatness of the passivation layer 220.

In one embodiment, a passivation layer 220 covering the interconnection layer 211 may be formed on the encapsulation layer 200 by coating.

Correspondingly, forming the first conductive bump 240 may include: patterning the passivation layer 220 using a photolithography process to expose a portion of the interconnection layer 211; and forming the first conductive bump 240 on the surface of the interconnection layer 211 exposed by the remaining passivation layer 220 using a bumping process.

Referring to FIG. 7, after forming the interconnection structure 210, the photoelectric sensing through-hole 250 may be formed in the encapsulation layer 200 on a side of the first conductive bump 240 facing away from the CMOS peripheral chip 100.

In one embodiment, forming the photoelectric sensing through-hole 250 may include: patterning the passivation layer 220 using a photolithography process to expose a portion of the encapsulation layer 200; and patterning the exposed encapsulation layer 200 using a laser cutting method, to form the photoelectric sensing through-hole 250 in the encapsulation layer 200.

In certain embodiments, at least one photoelectric sensing through-hole may be formed in the encapsulation layer using a photolithography process.

In certain embodiments, before forming the encapsulation layer on the carrier substrate, a prefab member may be bonded on the carrier substrate to define the position and shape of the photoelectric sensing through-hole. In the process of forming the encapsulation layer, the encapsulation layer may cover the prefab member, the CMOS peripheral chip, the capacitor and the interconnection pillar, and a top of the prefab member may be at least coplanar with one of the CMOS peripheral chip, the capacitor and the interconnection pillar who has a highest top. After the encapsulation layer is formed, a planarization process may be performed on the encapsulation layer until the prefab member is exposed.

Specifically, to facilitate process feasibility, the top of the prefab member may be the highest, such that the planarized encapsulation layer may still cover the prefab member, the CMOS peripheral chip, the capacitor, and the interconnection pillar.

Correspondingly, by removing the prefab member, the photoelectric sensing through-hole may be formed in the encapsulation layer, which may reduce the process difficulty of forming the photoelectric sensing through-hole.

It should be noted that in one embodiment, the opening size of the photoelectric sensing through-hole 250 may be determined according to the size of the light-transmitting cover plate 330, and the opening size of the photoelectric sensing through-hole 250 may be larger than the size of the light-transmitting cover plate 330, which may facilitate to place the light-transmitting cover plate 330 in the photoelectric sensing through-hole 250.

In addition, in one embodiment, for illustrative purposes, the quantity of the photosensitive components 390 may be one, and the quantity of the photoelectric sensing through-holes 250 may be correspondingly one as an example. In another embodiment, according to the quantity of lens components in the lens module, the quantity of the photosensitive components may be more than one, and the quantity of the photoelectric sensing through-holes may be correspondingly more than one. For example, when the lens module is a dual-camera lens module, the quantity of the photoelectric sensing through-holes may be correspondingly two.

Referring to FIG. 8, after the interconnection structure 210 is formed, the light-transmitting cover plate 330 may be placed in the photoelectric sensing through-hole 250 along the direction from the first conductive bump 240 to the encapsulation layer 200, to make the first chip bonding pad 310 attached to and electrically connected with the first conductive bump 240.

By placing the light-transmitting cover plate 330 in the corresponding photoelectric sensing through-hole 250, to achieve the package integration of the photosensitive component 390 (referring to FIG. 1), the CMOS peripheral chip 100, the capacitor 110, and the interconnection pillar 120.

The first chip bonding pad 310 may be attached to and electrically connected with the first conductive bump 240, such that the photoelectric sensing chip 300 may be electrically connected to the CMOS peripheral chip 100, the capacitor 110 and the interconnection pillar 120 through the interconnection structure 210 to achieve the electrical connection, thereby achieving circuit integration. Compared with the scheme where the photoelectric sensing chip, CMOS peripheral chip, and capacitor are packaged on the circuit board by a wire bonding process, the present disclosure may correspondingly omit the circuit board and the leads formed by the wire bonding process, which may not only simplify the electrical connection process, but also facilitate to improve the packaging efficiency, reduce the cost of the electrical connection process, and effectively reduce the total thickness of the subsequently formed lens module.

Moreover, the photosensitive component 390 may be made separately, and the process of integrating the CMOS peripheral chip 100, capacitor 110 and interconnection pillar 120 into the encapsulation layer may be carried out separately. Accordingly, the manufacturing process of the photosensitive component 390 may be prevented from affecting the integration of the CMOS peripheral chip 100, capacitor 110, and interconnection pillar 120. Similarly, the integration of the CMOS peripheral chip 100, capacitor 110, and interconnection pillar 120 may be prevented from affecting the photosensitive component 390, thereby facilitating to improve the packaging reliability and to reduce processing cost.

In one embodiment, after placing the light-transmitting cover plate 330 in the corresponding photoelectric sensing through-hole 250, an interatomic bonding in the contact surface between the first chip bonding pad 310 and the first conductive bump 240 may be achieved by a pressure welding process, to achieve the electrical connection between the first chip bonding pad 310 and the first conductive bump 240.

In certain embodiments, when the quantity of the photosensitive components is more than one, the quantity of the photoelectric sensing through-holes may be more than one. Correspondingly, placing the light-transmitting cover plate of the photosensitive component in the corresponding photoelectric sensing through-hole may include making the first chip bonding pad of each photoelectric sensing chip be attached to and electrically connected with the corresponding first conductive bump, such that each photoelectric sensing chip may be electrically connected with the CMOS peripheral chip, the capacitor and the interconnection pillar.

In one embodiment, after the light-transmitting cover plate 330 is placed in the corresponding photoelectric sensing through-hole 250, a gap may be formed between the sidewall of the photoelectric sensing through-hole 250 and the light-transmitting cover plate 330, which may facilitate to prevent the encapsulation layer 200 from generating stress on the light-transmitting cover plate 330, thereby significantly reducing the probability of the light-transmitting cover plate 330 being broken.

A width S of the gap may not be too small or too large. If the width S of the gap is too small, the process difficulty of placing the light-transmitting cover plate 330 in the photoelectric sensing through-hole 250 may increase. If the width S of the gap is too large, the size of the formed photoelectric sensing integrated system may increase, thereby increasing the size of the lens module. Therefore, in one embodiment, the width S of the gap may be in a range of approximately 5 μm-20 μm.

It should be noted that in one embodiment, the interconnection structure 210 may include the first conductive bump 240 and the rewiring structure 215 as an example for description. In another embodiment, when the first chip bonding pad is located on the side of the photoelectric sensing chip facing away from the light-transmitting cover plate, forming the interconnection structure may include achieving the electrical connections between CMOS peripheral chip, capacitor, interconnection pillar and photoelectric sensing chip using a wire bonding process.

Specifically, in certain embodiments, after the light-transmitting cover plate is placed in the corresponding photoelectric sensing through-hole, a wire bonding process may be used to form leads, to achieve the electrical connection between the CMOS peripheral chip, capacitor, interconnection pillar and the photoelectric sensing chip. In another embodiment, after forming the encapsulation layer on the carrier substrate, and before forming the photoelectric sensing through-hole, a first lead may be formed by a first wire bonding process, to achieve the electrical connection between the CMOS peripheral chip, the capacitor, and the interconnection pillar. After placing the light-transmitting cover plate in the corresponding photoelectric sensing through-hole, a second lead may be formed by a second wire bonding process, to achieve the electrical connection between the photoelectric sensing chip and the CMOS peripheral chip.

To reduce the process difficulty of the wire bonding process and improve the process operability, the surface of the CMOS peripheral chip facing away from the carrier substrate, the surface of the capacitor facing away from the carrier substrate, and the surface of the interconnection pillar facing away from the carrier substrate may be coplanar, such that the encapsulation layer may easily expose the second chip bonding pad of the CMOS peripheral chip, the electrode of the capacitor, and the end of the interconnection pillar facing away from the carrier substrate.

Referring to FIG. 6 and FIG. 7, in one embodiment, before placing the photosensitive component 390 (illustrated in FIG. 1) in the corresponding photoelectric sensing through-hole 250 (illustrated in FIG. 7), the packaging method may further include forming a bonding structure 230 on the encapsulation layer 200.

The bonding structure 230 may be configured to achieve a physical connection between the photosensitive component 390 and the encapsulation layer 200, to further improve the bonding strength between the photosensitive component 390 and the encapsulation layer 200.

Therefore, placing the light-transmitting cover plate 330 in the corresponding photoelectric sensing through-hole 250 may include bonding the peripheral region 300B (referring to FIG. 2) on the bonding structure 230. In one embodiment, the bonding structure 230 may be formed on the encapsulation layer 200 outside the photoelectric sensing through-hole 250.

Specifically, the bonding structure 230 may be located on both sides of the photoelectric sensing through-hole 250 to further improve the bonding strength between the photosensitive component 390 and the encapsulation layer 200. Correspondingly, patterning the encapsulation layer 200 to form the photoelectric sensing through-hole 250 may include patterning the encapsulation layer 200 between bonding structures 230, such that the bonding structure 230 may be located on both sides of the photoelectric sensing through-hole 250.

In certain embodiments, the bonding structure may be merely located on the encapsulation layer on the side of the photoelectric sensing through-hole away from the first conductive bump, which may improve the smoothness of the photosensitive component on the encapsulation layer while increasing the bonding strength between the photosensitive component and the encapsulation layer.

In one embodiment, the bonding structure 230 may be made of a photolithographable dry film. The photolithographable dry film may be adhesive and photolithographable, which may facilitate to reduce the process difficulty of forming the bonding structure 230. In another embodiment, the bonding structure may be made of photolithographable polyimide, photolithographable polybenzoxazole (PBO), or photolithographable benzocyclobutene (BCB).

Correspondingly, forming the bonding structure 230 may include: forming a bonding material layer on the encapsulation layer 200; and patterning the bonding material layer using a photolithography process. Thus, the remaining bonding material layer may be used as the bonding structure 230.

In one embodiment, to reduce the process difficulty of forming the bonding structure 230, before forming the photoelectric sensing through-hole 250, the bonding structure 230 may be formed. Specifically, after forming the passivation layer 220, the bonding structure 230 may be formed on the passivation layer 220.

In one embodiment, after forming the first conductive bump 240, the bonding structure 230 may be formed. In another embodiment, after forming the bonding structure 230, the first conductive bump 240 may be formed.

It should be noted that in certain embodiments, after forming the photoelectric sensing through-hole, the first conductive bump and the bonding structure may be formed.

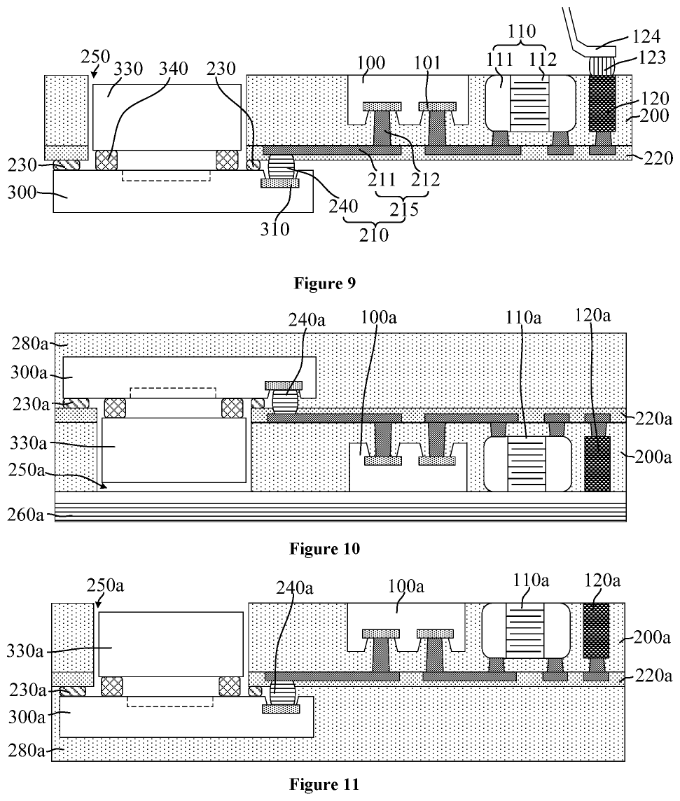

Referring to FIG. 9, after achieving the electrical connection between the CMOS peripheral chip 100, the capacitor 110, the interconnection pillar 120 and the photoelectric sensing chip 300, the method may further include performing a de-bonding process to remove the carrier substrate 260 (referring to FIG. 8).

By removing the carrier substrate 260, the surface of the encapsulation layer 200 facing away from the photoelectric sensing chip 300 may be exposed, thereby providing a process platform for subsequent assembly of lens components on the encapsulation layer 200.

Moreover, after the carrier substrate 260 is removed, the encapsulation layer 200 may expose the end of the interconnection pillar 120 facing away from the photoelectric sensing chip 300, to provide a process platform for subsequently achieving the electrical connection between the interconnection pillar 120 and the lens component.

In addition, after the electrical connection between the CMOS peripheral chip 100, the capacitor 110, the interconnection pillar 120 and the photoelectric sensing chip 300 is achieved, the carrier substrate 260 may be removed, which may facilitate to improve the process operability of the electrical connection.

In one embodiment, the CMOS peripheral chip 100, the capacitor 110, and the interconnection pillar 120 may be bonded to the carrier substrate 260 through the adhesive layer 270 (referring to FIG. 8). The adhesive layer 270 may be a foamed film. By heating the adhesive layer 270, the foamed surface of the adhesive layer 270 may lose viscosity, such that the carrier substrate 260 may be removed. After removing the carrier substrate 260, the adhesive layer 270 may be removed by a tear-off method.

In certain embodiments, according to the method of bonding the CMOS peripheral chip, capacitor, and interconnection pillar onto the carrier substrate, the carrier substrate may be removed by any other method.

It should be noted that in certain embodiments, the carrier substrate may be removed before placing at least the light-transmitting cover plate of the photosensitive component in the corresponding photoelectric sensing through-hole.

Referring to FIG. 9, the packaging method may further include forming a second conductive bump 123 at an end of the interconnection pillar 120 facing away from the photoelectric sensing chip 300.

After the lens component is subsequently assembled on the encapsulation layer 200, the second conductive bump 123 may be configured to achieve the electrical connection between the interconnection pillar 120 and the lens component, to achieve the electrical connection between the lens component and the photoelectric sensing integrated system.

Specifically, the second conductive bump 123 may be configured to be electrically connected with a voice coil motor holder (VCM) in the lens component. In one embodiment, the second conductive bump 123 may be a placed ball.

Therefore, the packaging method may further include forming a connection piece 124 on the second conductive bump 123. In one embodiment, the connection piece 124 may be a flexible connection piece (e.g., a flexible circuit board), to facilitate to achieve the electrical connection between the second conductive bump 123 and the voice coil motor holder.

FIGS. 10-11 illustrate schematic diagrams of semiconductor structures corresponding to certain stages of another packaging method of a photoelectric sensing integrated system consistent with various disclosed embodiments of the present disclosure. The same or similar features of the present embodiment and the embodiment associated with FIGS. 1-9 may not be repeated herein, while the difference may include that referring to FIG. 10, after achieving the electrical connection between the CMOS peripheral chip 100a, the capacitor 110a, the interconnection pillar 120a, and the photoelectric sensing chip 300a, the method may further include forming a cover layer 280a covering the photoelectric sensing chip 300a on the encapsulation layer 200a.

After the light-transmitting cover plate 330a is placed in the corresponding photoelectric sensing through-hole 250a, the photoelectric sensing chip 300a may be protruded from the encapsulation layer 200a. By forming the cover layer 280a, the cover layer 280a may cover the photoelectric sensing chip 300a. The surface of the cover layer 280a facing away from the light-transmitting cover plate 330a may be flat, thereby facilitating the subsequent packaging process.

Moreover, the cover layer 280a may protect the photoelectric sensing chip 300a, which may facilitate to reduce the influence of the subsequent packaging process on the photoelectric sensing chip 300a.

In one embodiment, the cover layer 280a may be formed on the passivation layer 220a by a molding process. Therefore, the cover layer 280a may be made of a molding material. The cover layer 280a made of the molding material may have functions such as insulation, sealing, and moisture proof, which may facilitate to further improve the performance and reliability of the formed lens module. Specifically, the cover layer 280a may be made of epoxy resin.

It should be noted that in the process of forming the cover layer 280a, under the blocking effect of the first conductive bump 240a and the bonding structure 230a located on the side of the photoelectric sensing through-hole 250a away from the first conductive bump 240a, the probability that the material of the cover layer 280a enters the photoelectric sensing through-hole 250a may be reduced, thereby reducing the influence of the formation of the cover layer 280a on the light-transmitting cover plate 330a.

It should be noted that to improve the process operability of forming the cover layer 280a and to reduce the influence of the formation process of the cover layer 280a on the light-transmitting cover plate 330a, before removing the carrier substrate 260a, the cover layer 280a may be formed. In certain embodiments, the cover layer may be formed after removing the carrier substrate.

Referring to FIG. 11, after forming the cover layer 280a, the method may further include removing the carrier substrate 260a. The specific description of the packaging method in the present embodiment may refer to the corresponding description in the packaging method in the embodiment associated with FIGS. 1-9, which may not be repeated herein.

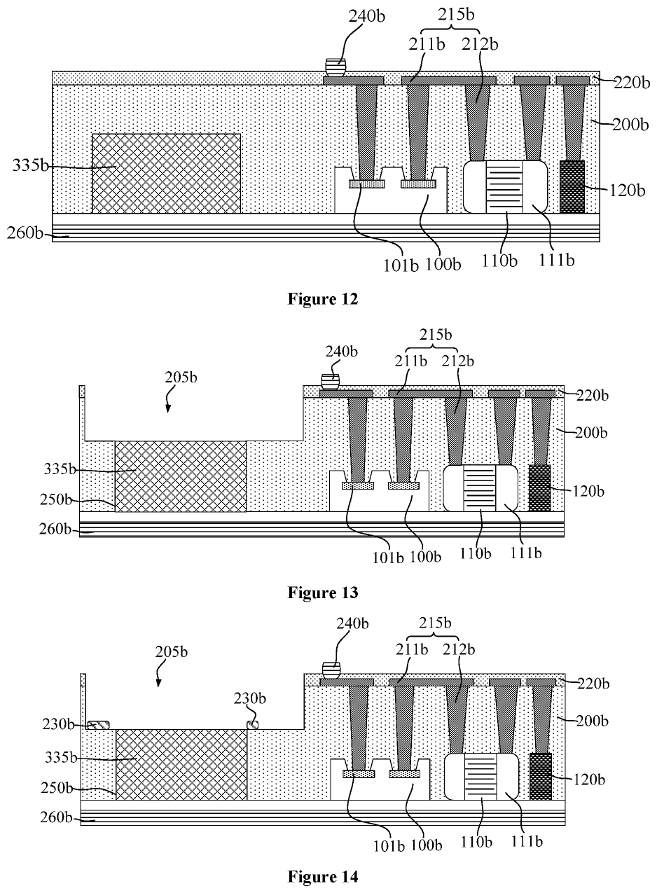

FIGS. 12-17 illustrate schematic diagrams of semiconductor structures corresponding to certain stages of another packaging method of a photoelectric sensing integrated system consistent with various disclosed embodiments of the present disclosure. The same or similar features of the present embodiment and the embodiment associated with FIGS. 1-9 may not be repeated herein, while the difference may include that referring to FIG. 16, both the light-transmitting cover plate 330b and the photoelectric sensing chip 300b may be placed in the photoelectric sensing through-hole 250b, and the photoelectric sensing chip 300b may be closer to the opening of the photoelectric sensing through-hole 250b with respect to the light-transmitting cover plate 330b.

The opening of the photoelectric sensing through-hole 250b may refer to the end of the photoelectric sensing through-hole 250b with a larger opening size.

The photoelectric sensing chip 300b may be placed in the photoelectric sensing through-hole 250b, which may facilitate the subsequent packaging process. Further, the encapsulation layer 200b may protect the photoelectric sensing chip 300b, which may facilitate to reduce the influence of the subsequent packaging process on the photoelectric sensing chip 300b.

Correspondingly, referring to FIG. 16, in one embodiment, in the photosensitive component (not labeled), the first chip bonding pad 310b of the photoelectric sensing chip 300b may face away from the light-transmitting cover plate 330b, which may facilitate to achieve the electrical connection between the photoelectric sensing chip 300b and each of the CMOS peripheral chip 100b, the capacitor 110b and the interconnection pillar 120b.

The packaging method in the present embodiment may be described in detail below with reference to the accompanying drawings.

Referring to FIG. 12, in the process of bonding the CMOS peripheral chip 100b, the capacitor 110b, and the interconnection pillar 120b on the carrier substrate 260b, a prefab member 335b may be bonded on the carrier substrate 260b for defining the position and shape of the subsequently formed photoelectric sensing through-hole.

In one embodiment, to reduce the process difficulty of forming the prefab member 335b and process difficulty of subsequently forming the encapsulation layer, the prefab member 335b may be configured to define the region in the photoelectric sensing through-hole for accommodating the light-transmitting cover plate 330b.

In one embodiment, to reduce the process cost, process complexity and process risk, the prefab member 335b may be made of Si.

In one embodiment, after temporarily bonding the prefab member 335b on the carrier substrate 260b, the method may further include attaching a thermal release film (not illustrated) on the surface of the prefab member 335b. The thermal release film may be used as a peeling layer between the prefab member 335b and the encapsulation layer 200b.

Specifically, the thermal release film may be sticky, such that the thermal release film may be attached to the surface of the prefab member 335b. After being heated, the thermal release film may lose viscosity, such that the thermal release film may be subsequently removed by heating the thermal release film, thereby removing the prefab member 335b.

Correspondingly, referring to FIG. 12, after forming the encapsulation layer 200b, the encapsulation layer 200b may cover the prefab member 335b, the CMOS peripheral chip 100b, the capacitor 110b, and the interconnection pillar 120b.

In one embodiment, the top of the encapsulation layer 200b may be above the top of the prefab member 335b, to provide a process platform for the subsequent formation of the stepped photoelectric sensing through-hole 250b (referring to FIG. 16), to achieve the assembly of the photoelectric sensing chip 300b in the photoelectric sensing through-hole 250b.

In one embodiment, the thickness of the encapsulation layer 200b may be reasonably set according to the thickness of the photosensitive component (not labeled), the thickness of the CMOS peripheral chip 100b, the thickness of the capacitor 110b, and the height of the interconnection pillar 120b. While increasing the assembly effect of the photoelectric sensing chip 300b and the light-transmitting cover plate 330b in the photoelectric sensing through-hole 250b (referring to FIG. 16), the process difficulty of the electrical connection process may be reduced.

The specific description of the encapsulation layer 200b may refer to the corresponding description in the packaging method in the embodiment associated with FIGS. 1-9, which may not be repeated herein.

Referring to FIG. 12, after forming the encapsulation layer 200b, the rewiring structure 215b may be formed on the surface of the encapsulation layer 200b facing away from the carrier substrate 260b for electrically connecting the second chip bonding pad 101b of the CMOS peripheral chip 100b, the electrode 111b of the capacitor 110b, and the interconnection pillar 120b. The first conductive bump 240b may be formed on the rewiring structure 215b, to be electrically connected with the first chip bonding pad 310b of the photoelectric sensing chip 300b (referring to FIG. 16).

In one embodiment, because the encapsulation layer 200b covers the CMOS peripheral chip 100b, the capacitor 110b, and the interconnection pillar 120b, the rewiring structure 215b may include: conductive pillars 212b located in the encapsulation layer 200b and connected with the second chip bonding pad 101b, the electrode 111b and the end of the interconnection pillar 120b facing away from the carrier substrate 260b, respectively; and the interconnection layer 211b located on the surface of the encapsulation layer 200b facing away from the carrier substrate 260b and connected with the plurality of conductive pillars 212b.

In one embodiment, the first conductive bump 240b may be formed by a bumping process. In other words, the first conductive bump 240b may be a bump.

It should be noted that after forming the rewiring structure 215b and before forming the first conductive bump 240b, the method may further include forming a passivation layer 220b covering the interconnection layer 211b on the encapsulation layer 200b.

Correspondingly, forming the first conductive bump 240b may include: patterning the passivation layer 220b to expose a portion of the interconnection layer 211b; and forming the first conductive bump 240b on the surface of the interconnection layer 211b exposed by the remaining passivation layer 220b using a bumping process.

The specific description of the rewiring structure 215b, the first conductive bump 240b and the passivation layer 220b may refer to the corresponding description in the packaging method in the embodiment associated with FIGS. 1-9, which may not be repeated herein.

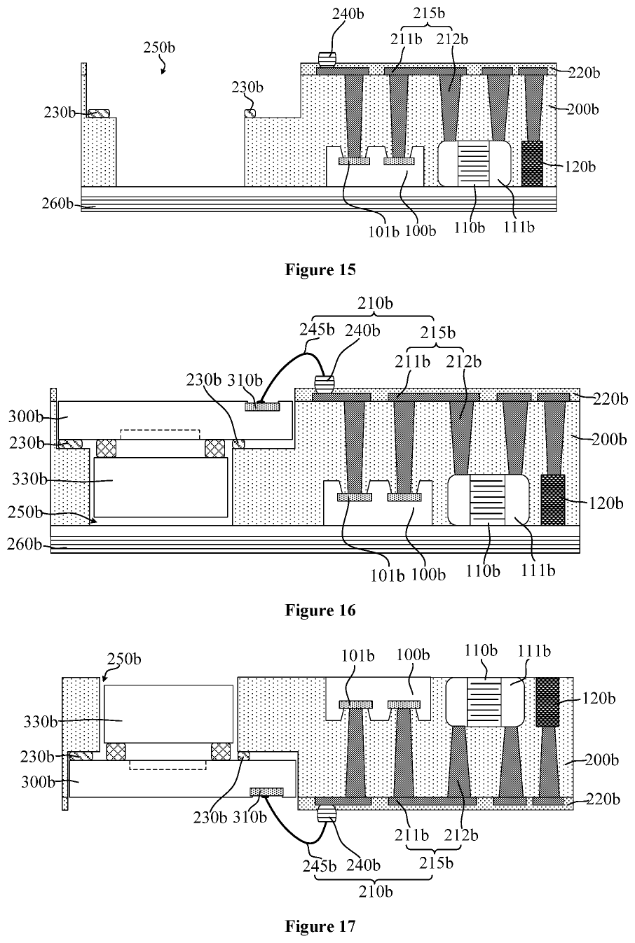

Referring to FIGS. 13-15, an opening 205b (referring to FIG. 13) may be formed in the encapsulation layer 200b, and the opening 205b may expose the prefab member 335b (referring to FIG. 13). The prefab member 335b may be removed from the opening 205b to form the photoelectric sensing through-hole 250b penetrating through the encapsulation layer 200b (referring to FIG. 15).

The opening 205b may be configured to provide a space for subsequent assembly of the photoelectric sensing chip 300b in the encapsulation layer 200b. Moreover, the opening 205b may expose the prefab member 335b, to provide a process platform for subsequently forming the photoelectric sensing through-hole penetrating through the encapsulation layer 200b.

Therefore, in one embodiment, the opening 205b may expose a portion of the encapsulation layer 200b, such that the formed photoelectric sensing through-hole 250b may have a step (not labeled). When the photosensitive component is subsequently placed in the photoelectric sensing through-hole 250b, the step may be configured to fix the photoelectric sensing chip 300b.

In one embodiment, the encapsulation layer 200b may be patterned by a laser cutting method, to form the opening 205b in the encapsulation layer 200. In certain embodiments, the opening may be formed in the encapsulation layer by a photolithography process.

In one embodiment, removing the prefab member 335b may include performing a heating treatment on the thermal release film (not labeled).

After performing the heating treatment, the thermal release film may lose viscosity, such that the thermal release film may be easily removed, to achieve a film release effect. Correspondingly, after removing the thermal release film, a gap may be formed between the prefab member 335b and the encapsulation layer 200b, such that the prefab member 335b may be easily taken out from the opening 205b, to form the photoelectric sensing through-hole 250b. Moreover, the film release method may facilitate to improve the smoothness of the sidewall of the photoelectric sensing through-hole 250b.

Referring to FIG. 13, in one embodiment, because the passivation layer 220b is formed on the encapsulation layer 200b, before forming the opening 205b, the method may further include patterning the passivation layer 220b.

Through patterning the passivation layer 220b, the remaining passivation layer 220b may expose a portion of the encapsulation layer 200b, thereby providing a process platform for patterning the encapsulation layer 200b. In one embodiment, a photolithography process may be used to pattern the passivation layer 220b.

Referring to FIG. 14, in one embodiment, after forming the opening 205b and before removing the prefab member 335b, the method may further include forming a bonding structure 230b on the encapsulation layer 200b exposed by the opening 205b.

The bonding structure 230b may be configured to achieve the subsequent physical connection between the photoelectric sensing chip 300b (referring to FIG. 16) and the encapsulation layer 200b, thereby further improving the bonding strength between the photosensitive component (not labeled) and the encapsulation layer 200b.

Therefore, after the photoelectric sensing through-hole 250b is formed (referring to FIG. 15), the bonding structure 230b may be located on the step of the photoelectric sensing through-hole 250b.

In one embodiment, the bonding structure 230b may be formed before forming the prefab member 335b. Therefore, in the process of forming the bonding structure 230b, the bottom of the opening 205b may have a flat surface, thereby reducing the process difficulty of forming the bonding structure 230b. In certain embodiments, the bonding structure may be formed after forming the photoelectric sensing through-hole.

It should be noted that in one embodiment, after forming the first conductive bump 240b, the bonding structure 230b may be formed. In certain embodiments, the first conductive bump may be formed after forming the bonding structure.

Referring to FIG. 16, along a direction from the first conductive bump 240b to the encapsulation layer 200b, after placing the photosensitive component (not labeled) in the photoelectric sensing through-hole 250b, the electrical connection between the first chip bonding pad 310b and the first conductive bump 240b may be achieved using a wire bonding process.

Because the photoelectric sensing chip 300b is also placed in the photoelectric sensing through-hole 250b, the wire bonding process may reduce the process difficulty of the electrical connection process, and may improve the process feasibility.

The light-transmitting cover plate 330b and the photoelectric sensing chip 300b may be placed in the corresponding photoelectric sensing through-hole 250b, and the lead 245b for electrically connecting the first chip bonding pad 310b and the first conductive bump 240b may be formed by a wire bonding process, to achieve the package integration and electrical integration of the photosensitive component and the CMOS peripheral chip 100b, the capacitor 110b as well as the interconnection pillar 120b.

Correspondingly, in one embodiment, the interconnection structure 210b may include the rewiring structure 215b, the first conductive bump 240b, and the lead 245b.

In one embodiment, the bonding structure 230b may be formed on the step of the photoelectric sensing through-hole 250b. In the process of placing the light-transmitting cover plate 330b and the photoelectric sensing chip 300b in the corresponding photoelectric sensing through-hole 250b, the peripheral region (not labeled) of the photoelectric sensing chip 300b may be bonded to the bonding structure 230b.

It should be noted that in one embodiment, by adjusting the thickness of the encapsulation layer 200b, after placing the light-transmitting cover plate 330b and the photoelectric sensing chip 300b in the corresponding photoelectric sensing through-hole 250b, the surface of the photoelectric sensing chip 300b facing away from the light-transmitting cover plate 330b may be coplanar with the surface of the encapsulation layer 200b facing away from the light-transmitting cover plate 330b. In certain embodiments, according to the thickness of the encapsulation layer, the photoelectric sensing chip may be protruded from the surface of the encapsulation layer facing away from the light-transmitting cover plate, or the surface of the photoelectric sensing chip facing away from the light-transmitting cover plate may be lower than the surface of the encapsulation layer facing away from the light-transmitting cover plate.

It should be noted that in one embodiment, before achieving the electrical connection between the first chip bonding pad 310b and the first conductive bump 240b, the carrier substrate 260b may be retained. The carrier substrate 260b may have support function during the process of placing the light-transmitting cover plate 330b and the photoelectric sensing chip 300b in the corresponding photoelectric sensing through-hole 250b and during the wire bonding process, which may facilitate to improve the process operability and may facilitate to reduce the process risk.

Therefore, referring to FIG. 17, after the electrical connection between the first chip bonding pad 310b and the first conductive bump 240b is achieved, the method may further include performing a de-bonding process to remove the carrier substrate 260b (referring to FIG. 16).

After the carrier substrate 260b is removed, the surface of the encapsulation layer 200b facing away from the photoelectric sensing chip 300b may be exposed, and the end of the interconnection pillar 120b facing away from the photoelectric sensing chip 300b may be exposed, which may provide a process platform for the subsequent assembly of the lens component and the electrical connection between the interconnection pillar 120b and the lens component.

In certain embodiments, according to actual process requirements, the carrier substrate may be removed after forming the photoelectric sensing through-hole and before placing the photosensitive component in the photoelectric sensing through-hole.

The specific description of the packaging method in the present embodiment may refer to the corresponding description in the packaging method in the embodiment associated with FIGS. 1-9, which may not be repeated herein.

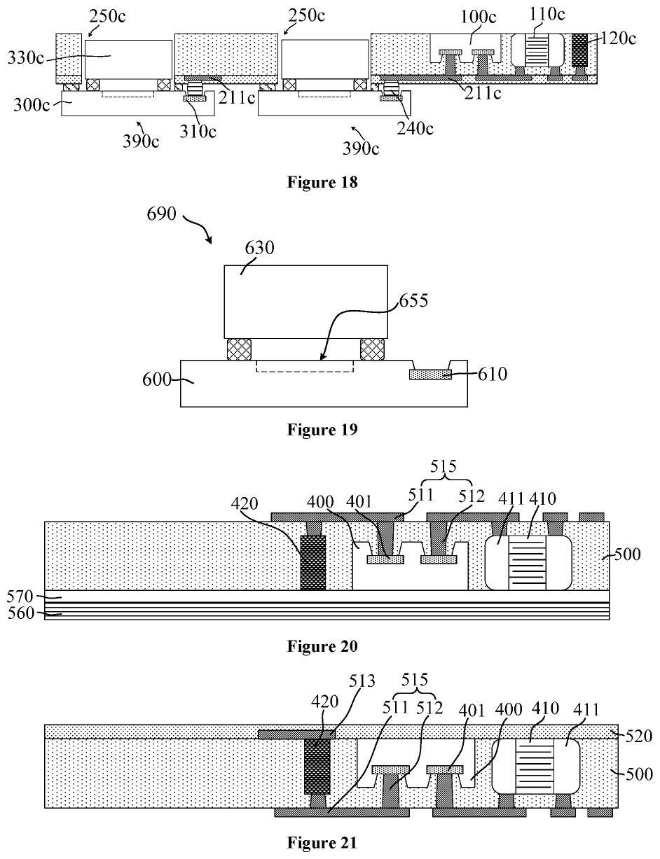

FIG. 18 illustrates a schematic diagram of a semiconductor structure corresponding to certain stages of another packaging method of a photoelectric sensing integrated system consistent with various disclosed embodiments of the present disclosure. The same or similar features of the present embodiment and the embodiment associated with FIGS. 1-9 may not be repeated herein, while the difference may include that the quantity of the photosensitive components 390c may be more than one, correspondingly, the quantity of the photoelectric sensing through-holes 250c may be more than one, and the photoelectric sensing through-holes 250c may have a quantity same as the photosensitive components 390c.

Correspondingly, placing at least the light-transmitting cover plate 330c of the photosensitive component 390c in the corresponding photoelectric sensing through-hole 250c may include making the first chip bonding pad 310c of each photoelectric sensing chip 300c be electrically connected with the corresponding first conductive bump 240c, to enable each photoelectric sensing chip 300c to be electrically connected with the CMOS peripheral chip 100c, the capacitor 110c, and the interconnection pillar 120c through the corresponding first conductive bump 240c and the interconnection layer 211c, thereby achieving the package integration and electrical integration of the plurality of photosensitive components 390c and the CMOS peripheral chip 100c, the capacitor 110c as well as the interconnection pillar 120c.

In one embodiment, for illustrative purposes, the to-be-formed lens module may be a dual-camera lens module as an example, the quantity of the photosensitive components 390c may be two, and correspondingly, the quantity of the photoelectric sensing through-holes 250c may be two.

The specific description of the packaging method in the present embodiment may refer to the corresponding description in the packaging method in the foregoing embodiments, which may not be repeated herein.

FIGS. 19-23 illustrate schematic diagrams of semiconductor structures corresponding to certain stages of another packaging method of a photoelectric sensing integrated system consistent with various disclosed embodiments of the present disclosure. The same or similar features of the present embodiment and the embodiment associated with FIGS. 1-9 may not be repeated herein, while the difference may include that referring to FIG. 23, in the process of placing at least the light-transmitting cover plate 630 of the photosensitive component 690 (illustrated in FIG. 19) in the corresponding photoelectric sensing through-hole 550, the light-signal-receiving-surface 655 of the photoelectric sensing chip 600 (referring to FIG. 19) may face away from the second chip bonding pad 401 of the CMOS peripheral chip 400.

The packaging method in the present embodiment may be described in detail below with reference to the accompanying drawings.

Referring to FIG. 19, at least one photosensitive component 690 may be formed. The photosensitive component 690 may include a photoelectric sensing chip 600 and a light-transmitting cover plate 630 disposed opposite to the photoelectric sensing chip 600.

In one embodiment, the photoelectric sensing chip 600 may include a photoelectric sensing region (not labeled) and a peripheral region (not labeled) surrounding the photoelectric sensing region. The photoelectric sensing chip 600 may have the light-signal-receiving-surface 655 disposed in the photoelectric sensing region.

In one embodiment, the photoelectric sensing chip 600 may further include a first chip bonding pad 610 formed in the peripheral region to achieve electrical connection between the photoelectric sensing chip 600 and any other circuit. Specifically, the first chip bonding pad 610 may face toward the light-transmitting cover plate 630.

The specific description of the photosensitive component 690 may refer to the corresponding description in the packaging method in the embodiment associated with FIGS. 1-9, which may not be repeated herein.

Referring to FIG. 20, a carrier substrate 560 may be provided. The CMOS peripheral chip 400, the capacitor 410, and the interconnection pillar 420 may be bonded on the carrier substrate 560.

In one embodiment, the interconnection pillar 420 may be configured to achieve the electrical connection between the photoelectric sensing chip 600 (referring to FIG. 19), the CMOS peripheral chip 400 and the capacitor 410.

In one embodiment, the CMOS peripheral chip 400, the capacitor 410, and the interconnection pillar 420 may be temporarily bonded on the carrier substrate 560 through an adhesive layer 570. In certain embodiments, the CMOS peripheral chip, the capacitor, and the interconnection pillar may be temporarily bonded on the carrier substrate by an electrostatic bonding method.

The specific description of the CMOS peripheral chip 400, the capacitor 410, the interconnection pillar 420, the carrier substrate 560, and temporary bonding may refer to the corresponding description in the packaging method in the embodiment associated with FIGS. 1-9, which may not be repeated herein.

Referring to FIG. 20, the encapsulation layer 500 may be formed on the carrier substrate 560, to at least fully fill the space between the CMOS peripheral chip 400, the capacitor 410 and the interconnection pillar 420.

In one embodiment, to improve the flatness of the encapsulation layer 500 and facilitate subsequent electrical connection process, the encapsulation layer 500 may cover the CMOS peripheral chip 400, the capacitor 410, and the interconnection pillar 420. In other words, the top of the encapsulation layer 500 may be above the CMOS peripheral chip 400, the capacitor 410 and the interconnection pillar 420.

The specific description of the encapsulation layer 500 may refer to the corresponding description in the packaging method in the embodiment associated with FIGS. 1-9, which may not be repeated herein.

Referring to FIG. 20, a first rewiring structure 515 may be formed on the surface of the encapsulation layer 500 facing away from the carrier substrate 560, and may be electrically connected with the second chip bonding pad 401, the electrode 411 of the capacitor 410, and the interconnection pillar 420.

In one embodiment, because the encapsulation layer 500 covers the CMOS peripheral chip 400, the capacitor 410 and the interconnection pillar 420, the first rewiring structure 515 may include: conductive pillars 512, located in the encapsulation layer 500 and connected with the second chip bonding pad 401, the electrode 411, and the end of the interconnection pillar 420 facing away from the carrier substrate 560, respectively; and the interconnection layer 511, located on the surface of the encapsulation layer 500 facing away from the carrier substrate 560 and connected with the plurality of conductive pillars 512.

In one embodiment, after forming the first rewiring structure 515, the method may further include: performing a de-bonding process to remove the carrier substrate 560 and the adhesive layer 570, to expose the surface of the encapsulation layer 500 facing away from the second chip bonding pad 401, thereby providing a process platform for subsequent formation of a second rewiring structure.

The specific description of the first rewiring structure 515 and the de-bonding process may refer to the corresponding description of the rewiring structure in the embodiment associated with FIGS. 1-9, which may not be repeated herein.

Referring to FIG. 21, after removing the carrier substrate 560 (referring to FIG. 20), a second rewiring structure 513 may be formed on the surface of the encapsulation layer 500 facing away from the first rewiring structure 515, and may be electrically connected with the interconnection pillar 420.

The first rewiring structure 515 may achieve the electrical connection between the CMOS peripheral chip 400, the capacitor 410, and the interconnection pillar 420, and the second rewiring structure 513 may be electrically connected with the interconnection pillar 420. Therefore, the photoelectric sensing chip 600 may be electrically connected to the CMOS peripheral chip 400, the capacitor 410, and the interconnection pillar 420 through the second rewiring structure 513.

In one embodiment, the second rewiring structure 513 may be a RDL layer. In one embodiment, the second rewiring structure 513 may be made of a same material as the interconnection layer 511, and the second rewiring structure 513 may be made of aluminum. In certain embodiments, the second rewiring structure may be made of any other applicable conductive material.

Specifically, forming the second rewiring structure 513 may include: forming an interconnection material layer on the surface of the encapsulation layer 500 facing away from the first rewiring structure 515, where the interconnection material layer may cover the interconnection pillar 420; and patterning the interconnection material layer to form the second rewiring structure 513 connected to the interconnection pillar 420.

It should be noted that after forming the second rewiring structure 513, the method may further include forming a passivation layer 520 covering the second rewiring structure 513 on the surface of the encapsulation layer 500 facing away from the first rewiring structure 515.

The specific description of the passivation layer 520 may refer to the corresponding description in the packaging method in the embodiment associated with FIGS. 1-9, which may not be repeated herein.

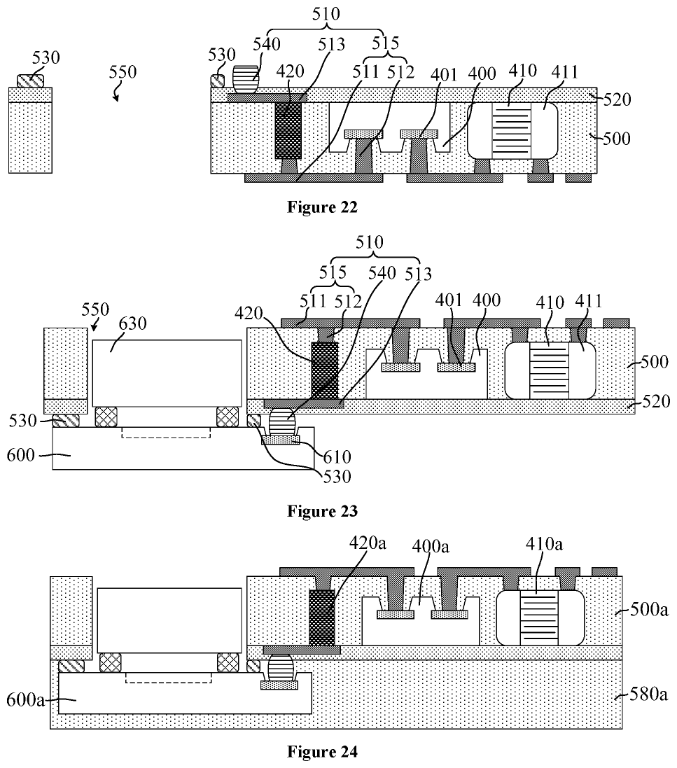

Referring to FIG. 22, a first conductive bump 540 may be formed on the second rewiring structure 513, and may be electrically connected with the first chip bonding pad 610 of the photoelectric sensing chip 600 (illustrated in FIG. 19).

In one embodiment, the first conductive bump 540, the first rewiring structure 515 and the second rewiring structure 513 may form the interconnection structure 510.

The specific description of the first conductive bump 540 may refer to the corresponding description in the packaging method in the embodiment associated with FIGS. 1-9, which may not be repeated herein.

Referring to FIG. 22, after forming the interconnection structure 510, a photoelectric sensing through-hole 550 may be formed in the encapsulation layer 500 on the side of the first conductive bump 540 away from the CMOS peripheral chip 400.

It should be noted that because the passivation layer 520 is formed on the encapsulation layer 500, before forming the photoelectric sensing through-hole 550, the method may further include: patterning the passivation layer 520. By patterning the passivation layer 520, the remaining passivation layer 520 may expose a portion of the encapsulation layer 500, thereby providing a process platform for patterning the encapsulation layer 500.

It should be noted that the packaging method may further include forming a bonding structure 530 on the encapsulation layer 500.

In one embodiment, the photoelectric sensing chip 600 may be located outside the photoelectric sensing through-hole 550. Therefore, the bonding structure 530 may be formed on the encapsulation layer 500 outside the photoelectric sensing through-hole 550. Specifically, the bonding structure 530 may be located on both sides of the photoelectric sensing through-hole 550.

In one embodiment, to reduce the process difficulty of forming the bonding structure 530, the bonding structure 530 may be formed before forming the photoelectric sensing through-hole 550. Specifically, after forming the passivation layer 520, the bonding structure 530 may be formed on the passivation layer 520.

In one embodiment, the bonding structure 530 may be formed after forming the first conductive bump 540. In another embodiment, the first conductive bump 540 may be formed after forming the bonding structure 530.

It should be noted that in certain embodiments, the first conductive bump and the bonding structure may be formed after forming the photoelectric sensing through-hole.

The specific description of the photoelectric sensing through-hole 550 and the bonding structure 530 may refer to the corresponding description in the packaging method in the embodiment associated with FIGS. 1-9, which may not be repeated herein.

Referring to FIG. 23, after forming the interconnection structure 510, along a direction from the second rewiring structure 513 to the first rewiring structure 515, the light-transmitting cover plate 630 may be placed in the corresponding photoelectric sensing through-hole 550, to make the first chip bonding pad 610 be attached to and electrically connected with the first conductive bump 540.

The first chip bonding pad 610 may be electrically connected to the first conductive bump 540, and the first conductive bump 540 may achieve the electrical connection between the CMOS peripheral chip 400 and the capacitor 410 through the second rewiring structure 513, the interconnection pillar 420, and the first rewiring structure 515, thereby achieving the package integration and electrical integration of the photosensitive component 690 (referring to FIG. 19) and the CMOS peripheral chip 400 as well as the capacitor 410.

It should be noted that the subsequent manufacturing process may further include: forming a second conductive bump (not illustrated) on the interconnection layer 511; and forming a connection piece (not illustrated) on the second conductive bump.

Because the interconnection layer 511 is located on the surface of the encapsulation layer 500 facing away from the photoelectric sensing chip 600, after the lens component is subsequently assembled on the encapsulation layer 500, the interconnection layer 511 may be electrically connected to the lens component through the second conductive bump (e.g., a placed ball) and the connection piece (e.g., a flexible circuit board), such that the photosensitive component 690, the CMOS peripheral chip 400 and the capacitor 410 may be electrically connected to voice coil motor holder of the lens component.

The specific description of the packaging method in the present embodiment may refer to the corresponding description in the packaging method in the embodiment associated with FIGS. 1-9, which may not be repeated herein.

FIG. 24 illustrates a schematic diagram of a semiconductor structure corresponding to certain stages of another packaging method of a photoelectric sensing integrated system consistent with various disclosed embodiments of the present disclosure. The same or similar features of the present embodiment and the embodiment associated with FIGS. 19-23 may not be repeated herein, while the difference may include that referring to FIG. 24, after achieving the electrical connection between the CMOS peripheral chip 400a, the capacitor 410a, the interconnection pillar 420a and the photoelectric sensing chip 600a, the method may further include forming a cover layer 580a covering the photoelectric sensing chip 600a on the encapsulation layer 500a.

The specific description of the packaging method in the preset embodiment may refer to the corresponding descriptions in the packaging methods in the embodiment associated with FIGS. 10-11 and embodiment associated with FIGS. 19-23, which may not be repeated herein.

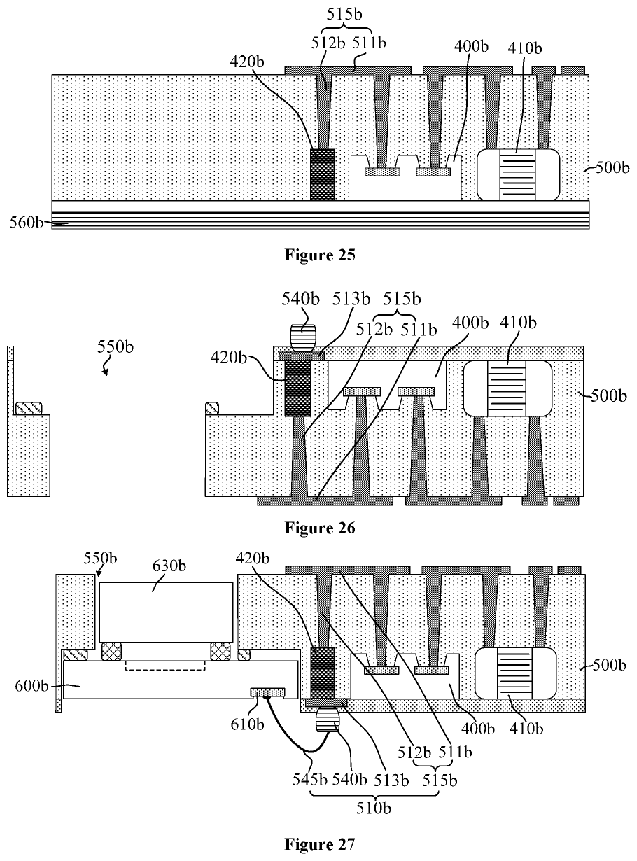

FIGS. 25-27 illustrate schematic diagrams of semiconductor structures corresponding to certain stages of another packaging method of a photoelectric sensing integrated system consistent with various disclosed embodiments of the present disclosure. The same or similar features of the present embodiment and the embodiment associated with FIGS. 19-23 may not be repeated herein, while the difference may include that referring to FIG. 27, the light-transmitting cover plate 630b and the photoelectric sensing chip 600b both may be placed in the photoelectric sensing through-hole 550b, and the photoelectric sensing chip 600b may be closer to the opening of the photoelectric sensing through-hole 550b with respect to the light-transmitting cover plate 630b. The opening of the photoelectric sensing through-hole 550b may refer to the end of the photoelectric sensing through-hole 550b with a larger opening size.

Correspondingly, referring to FIG. 27, in one embodiment, in the photosensitive component (not labeled), the first chip bonding pad 610b of the photoelectric sensing chip 600b may face away from the light-transmitting cover plate 630b, which may facilitate to achieve the electrical connection between the photoelectric sensing chip 600b and the CMOS peripheral chip 400b, the capacitor 410b and the interconnection pillar 420b.

Specifically, referring to FIG. 25 and FIG. 26, after forming the encapsulation layer 500b on the carrier substrate 560b (referring to FIG. 25) and before forming the photoelectric sensing through-hole 550b (referring to FIG. 26), a first rewiring structure 515b may be formed on the surface of the encapsulation layer 500b facing away from the carrier substrate 560b, which may be configured to electrically connect the second chip bonding pad (not labeled) of the CMOS peripheral chip 400b, the electrode of the capacitor 410b (not labeled) and interconnection pillar 420b. After forming the first rewiring structure 515b, the carrier substrate 560b may be removed. After removing the carrier substrate 560b, a second rewiring structure 513b may be formed on the surface of the encapsulation layer 500b facing away from the first rewiring structure 515b, to be electrically connected with the interconnection pillar 420b. A first conductive bump 540b may be formed on the second rewiring structure 513b, to be electrically connected with the first chip bonding pad.

Referring to FIG. 27, after forming the photoelectric sensing through-hole 550b, along the direction from the second rewiring structure 513b to the first rewiring structure 515b, after placing the light-transmitting cover plate 630b and the photoelectric sensing chip 600b in the corresponding photoelectric sensing through-hole 550b, the electrical connection between the first chip bonding pad (not labeled) and the first conductive bump 540b may be achieved by a wire bonding process.

After placing the light-transmitting cover plate 630b and the photoelectric sensing chip 600b in the corresponding photoelectric sensing through-hole 550b, the lead 545b for electrically connecting the first chip bonding pad and the first conductive bump 540b may be formed by a wire bonding process, which may facilitate to achieve the package integration and electrical integration of the photosensitive component (not labeled) and the CMOS peripheral chip 400b, the capacitor 410b, and the interconnection pillar 420b.

Correspondingly, in one embodiment, the interconnection structure 510b may include the first rewiring structure 515b, the second rewiring structure 513b, the first conductive bump 540b, and the lead 245b.

The specific description of the packaging method in the present embodiment may refer to the corresponding descriptions in the foregoing embodiment associated with FIGS. 12-17 and embodiment associated with FIGS. 19-23, which may not be repeated herein.

Correspondingly, the present disclosure also provides a photoelectric sensing integrated system.

FIG. 9 illustrates a schematic diagram of a photoelectric sensing integrated system consistent with various embodiments of the present disclosure. Referring to FIG. 9, the photoelectric sensing integrated system may include: a CMOS peripheral chip 100, a capacitor 110, an interconnection pillar 120, an encapsulation layer 200, at least one photosensitive component 390 (referring to FIG. 1), and an interconnection structure 210. The encapsulation layer may cover at least the sidewalls of the CMOS peripheral chip 100, the capacitor 110, and the interconnection pillar 120, and at least one photoelectric sensing through-hole 250 may be formed in the encapsulation layer. The photosensitive component 390 may include a photoelectric sensing chip 300 and a light-transmitting cover plate 330 oppositely disposed with the photoelectric sensing chip 300. The light-transmitting cover plate 330 may be attached to the photoelectric sensing chip 300, and at least the light-transmitting cover plate 330 of the photosensitive component 390 may be placed in the corresponding photoelectric sensing through-hole 250. The interconnection structure 210 may be configured to achieve electrical connection between the CMOS peripheral chip 100, the capacitor 110, the interconnection pillar 120, and the photoelectric sensing chip 300.

The CMOS peripheral chip 100, the capacitor 110 and the interconnection pillar 120 may be located in the encapsulation layer 200. The encapsulation layer 200 may fix the CMOS peripheral chip 100, the capacitor 110 and the interconnection pillar 120. At least the light-transmitting cover plate 330 of the photosensitive component 390 may be placed in the corresponding photoelectric sensing through-hole 250, thereby achieving the package integration of the CMOS peripheral chip 100, the capacitor 110, the interconnection pillar 120 and the photosensitive component 390. The electrical connection between the CMOS peripheral chip 100, the capacitor 110, the interconnection pillar 120 and the photoelectric sensing chip 300 may be achieved through the interconnection structure 210, such that the electrical integration of the CMOS peripheral chip 100, the capacitor 110, the interconnection pillar 120 and the photosensitive component 390 may be achieved.

Compared with the scheme where the photoelectric sensing chip, the CMOS peripheral chip, and the capacitor are packaged on the circuit board by a wire bonding process, the present disclosure may omit the circuit board, which may not only simplify the process steps of the electrical connection process, but also facilitate to improve the packaging efficiency, to reduce the cost of the electrical connection process, and to effectively reduce the total thickness of the subsequently formed lens module.

The photoelectric sensing integrated system may be described in detail below with reference to accompanying drawings.

A lens module may often include a camera component and a lens component fixed above the camera component and configured to form an image of a to-be-shot subject. The photosensitive component 390 may be used as the camera component of the lens module.

In one embodiment, the photoelectric sensing chip 300 may be an image sensor chip. The image sensor may be a semiconductor device that is capable of converting an optical image into electrical signals.

In one embodiment, the photoelectric sensing chip 300 may be a CMOS image sensor (CIS) chip. In another embodiment, the photoelectric sensing chip may be a charge coupled device (CCD) image sensor chip.

Referring to FIG. 2, the photoelectric sensing chip 300 may include a photoelectric sensing region 300A and a peripheral region 300B surrounding the photoelectric sensing region 300A. The photoelectric sensing chip 300 may include a light-signal-receiving-surface 355 located in the photoelectric sensing region 300A. The photoelectric sensing chip 300 may receive a sensing light radiation signal through the light-signal-receiving-surface 355.

Specifically, the light-signal-receiving-surface 355 may face the light-transmitting cover plate 330, thereby preventing the subsequent packaging process from polluting the imaging region of the photoelectric sensing chip 300 (i.e., the photoelectric sensing region 300A), preventing affecting the performance of the photoelectric sensing chip 300, and improving the imaging quality of the subsequently formed lens module.

It should be noted that the photoelectric sensing chip 300 may include a plurality of pixel units, e.g., a red pixel unit, a green pixel unit, and a blue pixel unit. Therefore, the photoelectric sensing chip 300 may include a plurality of semiconductor photosensitive devices (not illustrated), a plurality of filter films (not illustrated) on the plurality of semiconductor photosensitive devices, and a micro-lens 350 (referring to FIG. 2) on the filter film. A top surface of the micro lens 350 may be the light-signal-receiving-surface 355.

It should be noted that the photoelectric sensing chip 300 may further include a first chip bonding pad 310 disposed in the peripheral region 300B for achieving electrical connection between the photoelectric sensing chip 300 and any other circuit.

In one embodiment, the first chip bonding pad 310 may face toward the light-transmitting cover plate 330. In another embodiment, according to actual process requirements, the first chip bonding pad may face away from the light-transmitting cover plate.

Therefore, to achieve the electrical connection between the photoelectric sensing chip 300 and any other circuit, the light-transmitting cover plate 330 may cover the photoelectric sensing region 300A and may expose the first chip bonding pad 310. To ensure the normal performance of the photoelectric sensing chip 300, the light-transmitting cover plate 330 may be an infrared filter glass sheet or a fully light-transmitting glass sheet.

In one embodiment, the light-transmitting cover plate 330 may be an infrared filter glass sheet. When the lens module is in operation, the light-transmitting cover plate 330 may eliminate the influence of infrared light in the incident light on the performance of the photoelectric sensing chip 300, and may prevent the photoelectric sensing chip 300 from having problems such as color shift, which may facilitate to improve the image resolution and color reproduction, and correspondingly may improve the imaging effect of the lens module.

Specifically, the infrared filter glass sheet may be a blue glass infrared cut filter (IRCF). In another embodiment, the infrared filter glass sheet may include a glass sheet and an infrared cut coating on the surface of the glass.

At least the light-transmitting cover plate 330 of the photosensitive component 390 may be placed in the corresponding photoelectric sensing through-hole 250, such that the thickness of the light-transmitting cover plate 330 may be compatible with the thickness of the encapsulation layer 200, the thickness of the CMOS peripheral chip 100, the thickness of the capacitor 110, and the height of the interconnection pillar 120. In addition, considering the optical performance of the photosensitive component 390 and the thickness of the lens module, the thickness of the light-transmitting cover plate 330 may not be too small or too large.

In one embodiment, according to actual process requirements, the thickness of the light-transmitting cover plate 330 may be in a range of approximately 100 μm-300 μm, e.g., 150 μm, 200 μm, or 250 μm.

In one embodiment, the light-transmitting cover plate 330 may be attached to the photoelectric sensing chip 300 by an adhesive structure 340 disposed therebetween. The adhesive structure 340 may surround the light-signal-receiving-surface 355.

The adhesive structure 340 may be configured to achieve the physical connection between the photoelectric sensing chip 300 and the light-transmitting cover plate 330. Moreover, the light-transmitting cover plate 330, the adhesive structure 340 and the photoelectric sensing chip 300 may enclose a cavity 360 (referring to FIG. 1), to prevent the light-transmitting cover plate 330 from being in direct contact with the photoelectric sensing chip 300, and to prevent the light-transmitting cover plate 330 from affecting the optical performance of the photoelectric sensing chip 300.

In one embodiment, the adhesive structure 340 may surround the light-signal-receiving-surface 355, such that the light-transmitting cover plate 330 above the light-signal-receiving-surface 355 may be located on the photosensitive path of the photoelectric sensing chip 300, and, thus, ensuring the optical performance of the photoelectric sensing chip 300.

In one embodiment, the adhesive structure 340 may be made of a photolithographable dry film. The photolithographable dry film may be adhesive and photolithographable, and, thus, while achieving the physical connection between the photoelectric sensing chip 300 and the light-transmitting cover plate 330, may facilitate to reduce the process difficulty of forming the adhesive structure 340. In another embodiment, the adhesive structure may be made of photolithographable polyimide, photolithographable polybenzoxazole (PBO), or photolithographable benzocyclobutene (BCB).

In one embodiment, for illustrative purposes, a quantity of the photosensitive elements 390 may be one as an example. In another embodiment, according to the quantity of lens components in the lens module, the quantity of the photosensitive components may be more than one. For example, when the lens module is a dual-camera lens module, correspondingly, the quantity of the photosensitive components may be two.

The capacitor 110 may be a kind of passive components, which may be configured to achieve electrical connection with the photoelectric sensing chip 300, and may facilitate the photosensitive operation of the photoelectric sensing chip 300.

Therefore, the capacitor 110 may include an electrode 111, and the electrode 111 may be configured to achieve an electrical connection between the capacitor 110 and any other circuit.

In one embodiment, the capacitor 110 may be a ceramic capacitor. The ceramic capacitor may have advantages such as high operating temperature, large specific capacity, desired moisture resistance, low dielectric loss, and a wide range of capacitance temperature coefficients, and may have great prospects in electronic circuits.

Specifically, the capacitor 110 may be a multilayer ceramic capacitor (MLCC). The multilayer ceramic capacitor may be formed by: laminating ceramic dielectric membranes with printed electrodes (i.e., internal electrodes) in a staggered manner, forming a ceramic chip by one-time high-temperature sintering, and sealing the two ends of the ceramic chip with metal layers, where the metal layer may be used as the electrode 111 of the multilayer ceramic capacitor.

The multilayer ceramic capacitor may not only have the general characteristic “isolating direct current (DC) and passing alternating current (AC)” of capacitive elements, but also may have the advantages such as small size, large specific capacitance, long life, high reliability, and easy implementation of surface mount, to meet the demand for miniaturization, low cost, and large-capacity technology development of capacitive elements.

Correspondingly, the capacitor 110 may include a ceramic body 112 with internal electrodes (not labeled), and electrodes 111 located on both ends of the ceramic body 112.

It should be noted that when the capacitor 110 is a multilayer ceramic capacitor, the thickness of the multilayer ceramic capacitor may be dependent on the quantity of layers of the ceramic dielectric film. The larger the quantity of layers of the ceramic dielectric film, the larger the thickness of the multilayer ceramic capacitor.

In one embodiment, the thickness of the multilayer ceramic capacitor may be in a range of approximately 100 μm-400 μm, e.g., 150 μm, 200 μm, 250 μm, 300 μm, or 350 μm. According to the performance requirements of the capacitor 110, the multilayer ceramic capacitor with a suitable thickness may be selected.

The CMOS peripheral chip 100 may be another active element with specific functions in the camera component in addition to the photoelectric sensing chip 300. The CMOS peripheral chip 100 may be electrically connected with the photoelectric sensing chip 300, and may be configured to provide peripheral circuits, e.g., analog power supply circuit and digital power supply circuit, voltage buffer circuit, shutter circuit, shutter driving circuit, etc., for the photoelectric sensing chip 300.

The CMOS peripheral chip 100 may include a second chip bonding pad 101 for achieving electrical connection between the CMOS peripheral chip 100 and any other circuit.

The CMOS peripheral chip 100 may be made using integrated circuit manufacturing technology. Therefore, the CMOS peripheral chip 100 may often not only include devices such as NMOS devices, PMOS devices formed on a substrate, but also include an interlayer dielectric layer, a metal interconnection structure, and a bonding pad, etc.

In one embodiment, a surface of the CMOS peripheral chip 100 that exposes the second chip bonding pad 101 may be a front surface 102 of the chip (referring to FIG. 3), and a surface opposite to the front surface 102 of the chip may be a back surface 103 of the chip (referring to FIG. 3). The back surface 103 of the chip may refer to a bottom surface of the substrate on a side of the CMOS peripheral chip 100 facing away from the second chip bonding pad 101.

In certain embodiments, according to actual process conditions, the second chip bonding pad may be located on the back surface of the chip.

It should be noted that to reduce the process difficulty of the subsequent electrical connection between the CMOS peripheral chip 100, the capacitor 110 and the interconnection pillar 120, the thickness difference between the CMOS peripheral chip 100 and the capacitor 110 may not be too large or too small. Therefore, in one embodiment, the thickness of the CMOS peripheral chip 100 may be in a range of approximately 100 μm-300 μm, e.g., 150 μm, 200 μm, or 250 μm.

It should be noted that in one embodiment, the surface of the CMOS peripheral chip 100 facing toward the photoelectric sensing chip 300 may be lower than the surface of the capacitor 110 facing toward photoelectric sensing chip 300. In another embodiment, the surface of the CMOS peripheral chip facing toward photoelectric sensing chip may be coplanar with the surface of the capacitor facing toward photoelectric sensing chip.

The interconnection pillar 120 may be configured to be electrically connected with a voice coil motor holder (VCM) in the lens component.

In one embodiment, along an extension direction of the interconnection pillar 120, the interconnection pillar 120 may have opposite ends. One end of the interconnection pillar 120 may be configured to be electrically connected with the lens component of the lens module, and the other end of the interconnection pillar 120 may be configured to be electrically connected with the photoelectric sensing chip 300, the capacitor 110, and the CMOS peripheral chip 100. Therefore, the photoelectric sensing chip 300, the capacitor 110, and the CMOS peripheral chip 100 may be electrically connected with the lens component, thereby achieving the circuit conduction of the lens module.

The interconnection pillar 120 may have a columnar shape, and may have a certain height along the extension direction. In other words, the interconnection pillar 120 may be embedded in the encapsulation layer 200 and may be extended along a thickness direction of the encapsulation layer 200, which may facilitate the electrical connection between the photoelectric sensing chip 300, the capacitor 110 and the CMOS peripheral chip 100 with the lens component through the interconnection pillar 120.

Correspondingly, the interconnection pillar 120 may be made of a conductive material. In one embodiment, the interconnection pillar 120 may be made of a metal or a doped semiconductor with a certain resistance requirement. The interconnection pillar 120 made of such material may have desired conductivity and resistance controllability, such that the electrical characteristics of the interconnection pillar may meet the process requirements. Further, the interconnection pillar 120 made of such material may be prefabricated, such that the morphology and size of the interconnection pillar 120 may meet the process requirements.

To reduce the process difficulty of subsequently achieving electrical connection between the CMOS peripheral chip 100, the capacitor 110 and the interconnection pillar 120, the difference between the height of the interconnection pillar 120 and the thickness of the capacitor 110 may not be too large or too small. Therefore, in one embodiment, the height of the interconnection pillar 120 may be in a range of approximately 100 μm-400 μm, e.g., 150 μm, 200 μm, 250 μm, 300 μm, or 350 μm.

It should be noted that the interconnection pillar 120 may be easily formed by manufacturing. Therefore, in practical applications, the height of the interconnection pillar 120 may be equal to the thickness of the capacitor 110.

The encapsulation layer 200 may be configured to fix the CMOS peripheral chip 100, the capacitor 110, and the interconnection pillar 120, and may also be configured to separate fix the CMOS peripheral chip 100, the capacitor 110, and the interconnection pillar 120 from each other.

The encapsulation layer 200 may have functions such as insulation, sealing and moisture-proof, and may reduce the probability of the CMOS peripheral chip 100, the capacitor 110 and the interconnection pillar 120 being damaged, contaminated or oxidized, thereby facilitating to improve the performance and reliability of the formed lens module.

In one embodiment, the encapsulation layer 200 may be made of a molding material. In other words, the encapsulation layer may be formed by a molding process.

In one embodiment, the encapsulation layer 200 may be made of epoxy resin. Epoxy resin may have advantages such as low shrinkage, desired adhesion, desired corrosion resistance, desired electrical properties and low cost, and may be widely used as packaging materials for electronic devices and integrated circuits.

A thickness of the encapsulation layer 200 (not labeled) may need to be determined according to the thickness of the CMOS peripheral chip 100, the thickness of the capacitor 110, the height of the interconnection pillar 120, and actual process requirements, such that the encapsulation layer 200 may at least fully fill the space between the CMOS peripheral chip 100, the capacitor 110 and the interconnection pillar 120.

The photoelectric sensing through-hole 250 may be configured to accommodate at least the light-transmitting cover plate 330 of the photosensitive component 390, to achieve the package integration of the photosensitive component 390 and the CMOS peripheral chip 100, the capacitor 110, and the interconnection pillar 120.

In one embodiment, the photoelectric sensing through-hole 250 may be merely configured to accommodate the light-transmitting cover plate 330. In other words, the light-transmitting cover plate 330 may be placed in the corresponding photoelectric sensing through-hole 250, the photoelectric sensing chip 300 may be located outside the photoelectric sensing through-hole 250.

In one embodiment, a gap may be formed between the sidewall of the photoelectric sensing through-hole 250 and the light-transmitting cover plate 330, which may facilitate to reduce the assembly difficulty of the light-transmitting cover plate 330 and the photoelectric sensing through-hole 250. Further, the gap between the photoelectric sensing through-hole 250 and the light-transmitting cover plate 330 may facilitate to prevent the encapsulation layer 200 from generating stress on the light-transmitting cover plate 330, thereby significantly reducing the probability of the light-transmitting cover plate 330 being broken.

A width S (referring to FIG. 8) of the gap may not be too small or too large. If the width S of the gap is too small, the process difficulty of placing the light-transmitting cover plate 330 in the photoelectric sensing through-hole 250 may increase. If the width S of the gap is too large, the size of the formed photoelectric sensing integrated system may increase, thereby increasing the size of the lens module. Therefore, in one embodiment, the width S of the gap may be in a range of approximately 5 μm-20 μm.

It should be noted that in one embodiment, for illustrative purposes, the quantity of the photosensitive components 390 may be one, and the quantity of the photoelectric sensing through-holes 250 may be correspondingly one as an example. In another embodiment, according to the quantity of lens components in the lens module, the quantity of the photosensitive components may be more than one, and the quantity of the photoelectric sensing through-holes may be correspondingly more than one. For example, when the lens module is a dual-camera lens module, the quantity of the photoelectric sensing through-holes may be correspondingly two.

The interconnection structure 210 may be configured to achieve electrical connection between the CMOS peripheral chip 100, the capacitor 110, the interconnection pillar 120 and the photoelectric sensing chip 300.

In one embodiment, the interconnection structure 210 may include: a rewiring structure 215 formed on the surface of the encapsulation layer 200 facing toward the photoelectric sensing chip 300 for electrically connecting the second chip bonding pad 101, the electrode 111 of the capacitor 110, and the interconnection pillar 120; and a first conductive bump 240 formed on the rewiring structure 215 for electrically connecting with the first chip bonding pad 310.

The rewiring structure 215 may be configured to achieve the electrical connection between the CMOS peripheral chip 100, the capacitor 110 and the interconnection pillar 120.

In one embodiment, because the encapsulation layer 200 covers the CMOS peripheral chip 100, the capacitor 110, and the interconnection pillar 120, the rewiring structure 215 may include: a conductive pillar 212 located in the encapsulation layer 200 and connected with the second chip bonding pad 101, the electrode 111 and the end of the interconnection pillar 120 facing toward the photoelectric sensing chip 300, respectively; and the interconnection layer 211 located on the surface of the encapsulation layer 200 facing toward the photoelectric sensing chip 300 and connected with the plurality of conductive pillars 212.

The rewiring structure 215 may facilitate to reduce the distance between the CMOS peripheral chip 100, the capacitor 110 and the interconnection pillar 120, thereby facilitating the reduction of the size of the lens module. The thickness of the interconnection layer 211 may often be small, thereby facilitating to reduce the thickness of the lens module.

In one embodiment, the conductive pillar 212 may be mad of copper. In other words, the conductive pillar 212 may be a Cu pillar. The resistivity of copper may be substantially low. By selecting the copper material, the conductivity of the conductive pillar 212 may be improved. The filling of copper may be desired, which may facilitate to improve the formation quality of the conductive pillar 212 in the encapsulation layer. In certain embodiments, the conductive pillar may be made of any other applicable conductive material.

In one embodiment, the interconnection layer 211 may serve as a redistribution layer (RDL). The interconnection layer 211 may be electrically connected with the second chip bonding pad 101, the electrode 111, and the interconnection pillar 120 through the plurality of conductive pillars 212, and may be configured to redistribute the second chip bonding pad 101, the electrode 111, and the end of the interconnection pillar 120 facing toward the photoelectric sensing chip 300, to provide an electrical connection between the CMOS peripheral chip 100, the capacitor 110, the interconnection pillar 120 and any other circuit.

In one embodiment, the interconnection layer 211 may be made of aluminum. The aluminum process may be substantially simple and the process cost may be substantially low. Therefore, the selection of the aluminum interconnection layer may facilitate to reduce the process difficulty and process cost of the packaging process. In certain embodiments, the interconnection layer may be made of any other applicable conductive material.

The first conductive bump 240 may be electrically connected with the rewiring structure 215, and the first conductive bump 240 may be configured to be electrically connected with the first chip bonding pad 310, to achieve electrical connection between the photoelectric sensing chip 300, the CMOS peripheral chip 100, the capacitor 110 and the interconnection pillar 120. Moreover, through the first conductive bump 240, a physical connection between the photosensitive component 390 and the encapsulation layer 200 may be achieved.

In one embodiment, the first conductive bump 240 may be a bump. Compared with a placed ball, the first conductive bump 240 may have a substantially small thickness, thereby reducing the thickness of the subsequently formed lens module.

The photoelectric sensing integrated system may further include a passivation layer 220 on the surface of the encapsulation layer 200 facing toward the photoelectric sensing chip 300 to cover the interconnection layer 211.

The passivation layer 220 may be configured to insulate the interconnection layers 211, and may be configured to provide a process platform for the formation of the first conductive bump 240. In addition, the passivation layer 220 may have functions such as waterproof, anti-oxidation and anti-pollution.

In one embodiment, the passivation layer 220 may be made of a photosensitive material. Correspondingly, the passivation layer 220 may be formed through a photolithography process, which may facilitate to simplify the process steps and reduce the process cost.

In one embodiment, the passivation layer 220 may be made of a photosensitive polymer material. Specifically, the passivation layer 220 may be made of photosensitive polyimide (PI), photosensitive benzocyclobutene (BCB), photosensitive polybenzoxazole (PBO), or a combination thereof.

The passivation layer 220 made of such material may have low moisture absorption and high glass transition temperature, which may meet the process requirements. Moreover, in the process of forming the passivation layer 220, the passivation layer 220 may have desired leveling property, which may facilitate to improve the surface flatness of the passivation layer 220.

Because the passivation layer 220 covers the interconnection layer 211, the first conductive bump 240 may penetrate through the passivation layer 220 over the interconnection layer 211 and may be in contact with the interconnection layer 211.

In one embodiment, the photoelectric sensing integrated system may further include a bonding structure 230 on the encapsulation layer 200 for achieving bonding with the peripheral region 300B of the photoelectric sensing chip 300.

The bonding structure 230 may be configured to achieve a physical connection between the photosensitive component 390 and the encapsulation layer 200, to further improve the bonding strength between the photosensitive component 390 and the encapsulation layer 200.

In one embodiment, the photoelectric sensing chip 300 may be disposed outside the photoelectric sensing through-hole 250, and the bonding structure 230 may be located on the encapsulation layer 200 outside the photoelectric sensing through-hole 250.

Specifically, the bonding structure 230 may be located on both sides of the photoelectric sensing through-hole 250 to further improve the bonding strength between the photosensitive component 390 and the encapsulation layer 200. In certain embodiments, the bonding structure may be merely located on the encapsulation layer on the side of the photoelectric sensing through-hole away from the first conductive bump, which may improve the smoothness of the photosensitive component on the encapsulation layer while increasing the bonding strength between the photosensitive component and the encapsulation layer

In one embodiment, the bonding structure 230 may be made of a photolithographable dry film. The photolithographable dry film may be adhesive and photolithographable, which may facilitate to reduce the process difficulty of forming the bonding structure 230 while achieving the physical connection between the photosensitive component 390 and the encapsulation layer 200. In another embodiment, the bonding structure may be made of photolithographable polyimide, photolithographable polybenzoxazole (PBO), or photolithographable benzocyclobutene (BCB).

In one embodiment, the passivation layer 220 may be formed on the surface of the encapsulation layer 200 facing toward the photoelectric sensing chip 300, and, thus, the bonding structure may be formed on the passivation layer 220.

It should be noted that in one embodiment, the interconnection structure 210 may include the first conductive bump 240 and the rewiring structure 215 as an example. In certain embodiments, when the first chip bonding pad is disposed on the side of the photoelectric sensing chip facing away from the light-transmitting cover plate, the interconnection structure may further include a lead, to provide the electrical connection between the photoelectric sensing chip and each of the CMOS peripheral chip, the capacitor, and the interconnection pillar.

The lead may be formed by a wire bonding process. To reduce the process difficulty of the wire bonding process and improve the process operability, the surface of the CMOS peripheral chip facing toward the photoelectric sensing chip, the surface of the capacitor facing toward the photoelectric sensing chip, and the surface of the interconnection pillar facing toward the photoelectric sensing chip may be coplanar, such that the encapsulation layer may easily expose the second chip bonding pad of the CMOS peripheral chip, the electrode of the capacitor, and the end of the interconnection pillar facing toward the photoelectric sensing chip.

In one embodiment, the photoelectric sensing integrated system may further include a second conductive bump 123 at an end of the interconnection pillar 120 facing away from the photoelectric sensing chip 300.

After the lens component is assembled on the encapsulation layer 200, the second conductive bump 123 may be configured to achieve the electrical connection between the interconnection pillar 120 and the lens component, to achieve the electrical connection between the lens component and the photoelectric sensing integrated system.

Specifically, the second conductive bump 123 may be configured to be electrically connected with a voice coil motor holder (VCM) in the lens component. In one embodiment, the second conductive bump 123 may be a placed ball.

Therefore, the photoelectric sensing integrated system may further include a connection piece 124 on the second conductive bump 123. In one embodiment, the connection piece 124 may be a flexible connection piece (e.g., a flexible circuit board), to facilitate to achieve the electrical connection between the second conductive bump 123 and the voice coil motor holder.

The photoelectric sensing integrated system may be formed by the packaging method in the embodiment associated with FIGS. 1-9, or may be formed by any other packaging method. The specific description of the photoelectric sensing integrated system may refer to corresponding description in the packaging method in embodiment associated with FIGS. 1-9, which may not be repeated herein.

FIG. 11 illustrates a schematic diagram of another photoelectric sensing integrated system consistent with various embodiments of the present disclosure. The same or similar features of the present embodiment and the embodiment associated with FIG. 9 may not be repeated herein, while the difference may include that referring to FIG. 11, the photoelectric sensing integrated system may further include a cover layer 280a covering the photoelectric sensing chip 300a on the encapsulation layer 200a.

The cover layer 280a may cover the photoelectric sensing chip 300a. The surface of the cover layer 280a facing away from the light-transmitting cover plate 330a may be flat, thereby facilitating the subsequent packaging process.

Further, the cover layer 280a may protect the photoelectric sensing chip 300a, which may facilitate to reduce the influence of the subsequent packaging process on the photoelectric sensing chip 300a.

Specifically, the cover layer 280a may be formed on the passivation layer 220a. In one embodiment, the cover layer 280a may be made of a molding material. In other words, the cover layer 280a may be formed by a molding process. Specifically, the cover layer 280a may be made of epoxy resin.

It should be noted that under the blocking effect of the first conductive bump 240a and the bonding structure 230a located on the side of the photoelectric sensing through-hole 250a away from the first conductive bump 240a, the probability that the material of the cover layer 280a enters the photoelectric sensing through-hole 250a may be substantially small, thereby reducing the influence of the formation of the cover layer 280a on the light-transmitting cover plate 330a.

The photoelectric sensing integrated system may be formed by the packaging method in the embodiment associated with FIGS. 10-11, or may be formed by any other packaging method. The specific description of the photoelectric sensing integrated system may refer to corresponding description in the packaging method in the embodiment associated with FIGS. 10-11, which may not be repeated herein.

FIG. 17 illustrates a schematic diagram of another photoelectric sensing integrated system consistent with various embodiments of the present disclosure. The same or similar features of the present embodiment and the embodiment associated with FIG. 9 may not be repeated herein, while the difference may include that referring to FIG. 17, both the light-transmitting cover plate 330b and the photoelectric sensing chip 300b may be placed in the photoelectric sensing through-hole 250b, and the photoelectric sensing chip 300b may be closer to the opening of the photoelectric sensing through-hole 250b with respect to the light-transmitting cover plate 330b. The opening of the photoelectric sensing through-hole 250b may refer to the end of the photoelectric sensing through-hole 250b with a larger opening size.

The photoelectric sensing chip 300b may be placed in the photoelectric sensing through-hole 250b, which may facilitate the subsequent packaging process. Further, the encapsulation layer 200b may protect the photoelectric sensing chip 300b, which may facilitate to reduce the influence of the subsequent packaging process on the photoelectric sensing chip 300b.

Correspondingly, in one embodiment, in the photosensitive component (not labeled), the first chip bonding pad 310b of the photoelectric sensing chip 300b may face away from the light-transmitting cover plate 330b, which may facilitate to achieve the electrical connection between the photoelectric sensing chip 300b and each of the CMOS peripheral chip 100b, the capacitor 110b and the interconnection pillar 120b.

Correspondingly, the interconnection structure 210b may include the rewiring structure 215b, the first conductive bump 240b, and the lead 245b. The rewiring structure 215b may be formed on the surface of the encapsulation layer 200b facing toward the photoelectric sensing chip 300b for electrically connecting the second chip bonding pad 101b of the CMOS peripheral chip 100b, the electrode 111b of the capacitor 110b, and the interconnection pillar 120b. The first conductive bump 240b may be formed on the rewiring structure 215b. The lead 245b may be configured to electrically connect the first chip bonding pad 310b and the first conductive bump 240b.

Because the photoelectric sensing chip 300b is also placed in the photoelectric sensing through-hole 250b, the lead 245b may reduce the process difficulty of the electrical connection process, and may improve the process feasibility.

The rewiring structure 215b may achieve the electrical connection between the CMOS peripheral chip 100b, the capacitor 110b, and the interconnection pillar 120b, and the first conductive bump and the lead 245 may achieve electrical connection between the rewiring structure 215b and the first chip bonding pad 310b, to achieve the package integration and electrical integration of the photosensitive component (not labeled) and the CMOS peripheral chip 100b, the capacitor 110b as well as the interconnection pillar 120b.

In one embodiment, the photoelectric sensing integrated system may further include a bonding structure 230b on the encapsulation layer 200b, for achieving bonding with the peripheral region (not labeled) of the photoelectric sensing chip 300b.

In one embodiment, because the photoelectric sensing chip 300b is located in the photoelectric sensing through-hole 250b, the bonding structure 230b may be located on the step of the photoelectric sensing through-hole 250b.

It should be noted that in one embodiment, the surface of the photoelectric sensing chip 300b facing away from the light-transmitting cover plate 330b may be coplanar with the surface of the encapsulation layer 200b facing away from the light-transmitting cover plate 330b. In certain embodiments, according to the thickness of the encapsulation layer, the photoelectric sensing chip may be protruded from the surface of the encapsulation layer facing away from the light-transmitting cover plate, or the surface of the photoelectric sensing chip facing away from the light-transmitting cover plate may be lower than the surface of the encapsulation layer facing away from the light-transmitting cover plate.

The photoelectric sensing integrated system may be formed by the packaging method in the embodiment associated with FIGS. 12-17, or may be formed by any other packaging method. The specific description of the photoelectric sensing integrated system may refer to corresponding description in the packaging method in the embodiment associated with FIGS. 12-17, which may not be repeated herein.

FIG. 18 illustrates a schematic diagram of another photoelectric sensing integrated system consistent with various embodiments of the present disclosure. The same or similar features of the present embodiment and the embodiment associated with FIG. 9 may not be repeated herein, while the difference may include that referring to FIG. 18, the quantity of the photosensitive components 390c may be more than one, correspondingly, the quantity of the photoelectric sensing through-holes 250c may be more than one, and the photoelectric sensing through-holes 250c may have a quantity same as the photosensitive components 390c.

Correspondingly, the first chip bonding pad 310c of each photoelectric sensing chip 300c may be electrically connected with the corresponding first conductive bump 240c, to enable each photoelectric sensing chip 300c to be electrically connected with the CMOS peripheral chip 100c, the capacitor 110c, and the interconnection pillar 120c through the corresponding first conductive bump 240c and the interconnection layer 211c, thereby achieving the package integration and electrical integration of the plurality of photosensitive components 390c and the CMOS peripheral chip 100c, the capacitor 110c as well as the interconnection pillar 120c.

In one embodiment, for illustrative purposes, the lens module may be a dual-camera lens module as an example, the quantity of the photosensitive components 390c may be two, and correspondingly, the quantity of the photoelectric sensing through-holes 250c may be two.

The photoelectric sensing integrated system may be formed by the packaging method in the embodiment associated with FIG. 18, or may be formed by any other packaging method. The specific description of the photoelectric sensing integrated system may refer to corresponding description in the packaging method in the embodiment associated with FIG. 18, which may not be repeated herein.

FIG. 23 illustrates a schematic diagram of another photoelectric sensing integrated system consistent with various embodiments of the present disclosure. The same or similar features of the present embodiment and the embodiment associated with FIG. 9 may not be repeated herein, while the difference may include that referring to FIG. 23, the light-signal-receiving-surface 655 of the photoelectric sensing chip 600 (referring to FIG. 19) may face away from the second chip bonding pad 401 of the CMOS peripheral chip 400.

In one embodiment, the first chip bonding pad 610 of the photoelectric sensing chip 600 may face toward the light-transmitting cover plate 630, and the photoelectric sensing chip 600 may be located outside the photoelectric sensing through-hole 550.

In one embodiment, the interconnection pillar 420 may be configured to achieve the electrical connection between the photoelectric sensing chip 600, the CMOS peripheral chip 400, and the capacitor 410.

Correspondingly, the interconnection structure 510 may include the first rewiring structure 515, the second rewiring structure 513, and the first conductive bump 540. The first rewiring structure 515 may be formed on the surface of the encapsulation layer 500 facing toward the photoelectric sensing chip 600, and may be electrically connected with the second chip bonding pad 401, the electrode 411 of the capacitor 410, and the interconnection pillar 420. The second rewiring structure 513 may be formed on the surface of the encapsulation layer 500 facing away from the first rewiring structure 515, and may be electrically connected with the interconnection pillar 420. The first conductive bump 540 may be formed on the second rewiring structure 513, and may be electrically connected with the first chip bonding pad 610.

In one embodiment, because the encapsulation layer 500 covers the CMOS peripheral chip 400, the capacitor 410 and the interconnection pillar 420, the first rewiring structure 515 may include: conductive pillars 512, located in the encapsulation layer 500 and connected with the second chip bonding pad 401, the electrode 411, and the end of the interconnection pillar 420 facing away from the carrier substrate 560, respectively; and the interconnection layer 511, located on the surface of the encapsulation layer 500 facing toward the photoelectric sensing chip 600 and connected with the plurality of conductive pillars 512.

The specific description of the first rewiring structure 515 and the first conductive bump 540 may refer to the corresponding description of the rewiring structure and the first conductive bump in the embodiment associated with FIGS. 1-9, which may not be repeated herein.

The first rewiring structure 515 may achieve the electrical connection between the CMOS peripheral chip 400, the capacitor 410, and the interconnection pillar 420, and the second rewiring structure 513 may be electrically connected with the interconnection pillar 420. Therefore, the photoelectric sensing chip 600 may be electrically connected to the CMOS peripheral chip 400, the capacitor 410, and the interconnection pillar 420 through the second rewiring structure 513 and the first conductive bump 540.

In one embodiment, the second rewiring structure 513 may be a RDL layer. In one embodiment, the second rewiring structure 513 may be made of a same material as the interconnection layer 511, and the second rewiring structure 513 may be made of aluminum. In certain embodiments, the second rewiring structure may be made of any other applicable conductive material.

In one embodiment, the photoelectric sensing integrated system may further include a passivation layer 520. The passivation layer 520 may be formed on the surface of the encapsulation layer 500 facing away from the first rewiring structure 515, and may cover the second rewiring structure 513. The specific description of the passivation layer 520 may refer to the corresponding description in the packaging method in the embodiment associated with FIGS. 1-9, which may not be repeated herein.

In one embodiment, the photoelectric sensing integrated system may further include a bonding structure 530 on the encapsulation layer 500, for achieving bonding with the peripheral region (not labeled) of the photoelectric sensing chip 600.

In one embodiment, the photoelectric sensing chip 600 may be located outside the photoelectric sensing through-hole 550. Therefore, the bonding structure 530 may be formed on the encapsulation layer 500 outside the photoelectric sensing through-hole 550. Specifically, the bonding structure 530 may be located on the passivation layer 520 on both sides of the photoelectric sensing through-hole 550. The specific description of the bonding structure 530 may refer to the corresponding description in the packaging method in the embodiment associated with FIGS. 1-9, which may not be repeated herein.

In one embodiment, the photoelectric sensing integrated system may further include a second conductive bump (not illustrated) formed on the interconnection layer 511, and a connection piece (not illustrated) formed on the second conductive bump.

Because the interconnection layer 511 is located on the surface of the encapsulation layer 500 facing away from the photoelectric sensing chip 600, after the lens component is subsequently assembled on the encapsulation layer 500, the interconnection layer 511 may be electrically connected to the lens component through the second conductive bump (e.g., a placed ball) and the connection piece (e.g., a flexible circuit board), such that the photosensitive component 690, the CMOS peripheral chip 400 and the capacitor 410 may be electrically connected to voice coil motor holder of the lens component.

It should be noted that in one embodiment, for illustrative purposes, the quantity of the photosensitive components 690 may be one, and the quantity of the photoelectric sensing through-holes 550 may be correspondingly one as an example. In another embodiment, according to the quantity of lens components in the lens module, the quantity of the photosensitive components may be more than one, and the quantity of the photoelectric sensing through-holes may be correspondingly more than one. For example, when the lens module is a dual-camera lens module, the quantity of the photoelectric sensing through-holes may be correspondingly two.

The photoelectric sensing integrated system may be formed by the packaging method in the embodiment associated with FIGS. 19-23, or may be formed by any other packaging method. The specific description of the photoelectric sensing integrated system may refer to corresponding description in the packaging method in the embodiment associated with FIGS. 19-23, which may not be repeated herein.

FIG. 24 illustrates a schematic diagram of another photoelectric sensing integrated system consistent with various embodiments of the present disclosure. The same or similar features of the present embodiment and the embodiment associated with FIG. 23 may not be repeated herein, while the difference may include that referring to FIG. 24, the photoelectric sensing integrated system may further include a cover layer 580a covering the photoelectric sensing chip 600a on the encapsulation layer 500a.

The photoelectric sensing integrated system may be formed by the packaging method in the embodiment associated with FIG. 24, or may be formed by any other packaging method. The specific description of the photoelectric sensing integrated system may refer to corresponding description in the packaging method in the embodiment associated with FIGS. 10-11, the embodiment associated with FIGS. 19-23, and the embodiment associated with FIG. 24, which may not be repeated herein.

FIG. 27 illustrates a schematic diagram of another photoelectric sensing integrated system consistent with various embodiments of the present disclosure. The same or similar features of the present embodiment and the embodiment associated with FIG. 23 may not be repeated herein, while the difference may include that referring to FIG. 27, both the light-transmitting cover plate 630b and the photoelectric sensing chip 600b may be placed in the photoelectric sensing through-hole 550b, and the photoelectric sensing chip 600b may be closer to the opening of the photoelectric sensing through-hole 550b with respect to the light-transmitting cover plate 630b. The opening of the photoelectric sensing through-hole 550b may refer to the end of the photoelectric sensing through-hole 550b with a larger opening size.

Correspondingly, in one embodiment, in the photosensitive component (not labeled), the first chip bonding pad 610b of the photoelectric sensing chip 600b may face away from the light-transmitting cover plate 630b, which may facilitate to provide the electrical connection between the photoelectric sensing chip 600b and each of the CMOS peripheral chip 400b, the capacitor 410b and the interconnection pillar 420b. Further, the photoelectric sensing through-hole 550b may have a step, to achieve the assembly of the photoelectric sensing chip 600b in the photoelectric sensing through-hole 550b.

Correspondingly, in one embodiment, the interconnection structure 510b may include the first rewiring structure 515b, the second rewiring structure 513b, the first conductive bump 540b, and the lead 545b. The first rewiring structure 515b may be formed on the surface of the encapsulation layer 500b facing away from the photoelectric sensing chip 600b for electrically connecting the second chip bonding pad (not labeled) of the CMOS peripheral chip 400b, the electrode (not labeled) of the capacitor 410b, and the interconnection pillar 420b. The second rewiring structure 513b may be formed on the surface of the encapsulation layer 500b facing away from the first rewiring structure 515b and may be electrically connected with the interconnection pillar 420b. The first conductive bump 540b may be formed on the second rewiring structure 513b. The lead 545b may be configured to electrically connect the first chip bonding pad 610b and the first conductive bump 540b.

The photoelectric sensing integrated system may be formed by the packaging method in the embodiment associated with FIGS. 25-27, or may be formed by any other packaging method. The specific description of the photoelectric sensing integrated system may refer to corresponding descriptions in the packaging method in the embodiment associated with FIGS. 12-17, the embodiment associated with FIGS. 19-23, and the embodiment associated with FIGS. 25-27, which may not be repeated herein.

Correspondingly, the present disclosure also provides a lens module. In one embodiment, the lens module may include a photoelectric sensing integrated system in any of the disclosed embodiments, and a lens component electrically connected with the interconnection pillar or the interconnection structure.

In the photoelectric sensing integrated system, the CMOS peripheral chip, the capacitor, the interconnection pillar and the photoelectric sensing chip may be electrically connected. Through configuring the lens component to be electrically connected with the interconnection pillar or the interconnection structure, the electrical connection between the photoelectric sensing integrated system and the lens component may be achieved.

In one embodiment, the electrical connection between the photoelectric sensing integrated system and the lens component may be achieved through the second conductive bump and the connection piece in the photoelectric sensing integrated system.

Specifically, the connection piece may be configured to be electrically connected with the voice coil motor holder in the lens component.

In one embodiment, the packaging process of the photoelectric sensing integrated system may be substantially simple, and the thickness of the photoelectric sensing integrated system may be substantially small, which may correspondingly simplify the packaging process of the lens module and reduce the total thickness of the lens module.

Correspondingly, the present disclosure provides an electronic device. In one embodiment, the electronic device may include a lens module in any of the disclosed embodiments.

The packaging process of the lens module may be substantially simple, and the total thickness of the lens module may be substantially small, which may correspondingly facilitate to increase the production capacity of the electronic device and reduce the thickness of the electronic device, thereby improving economic benefits and user satisfaction.

The present disclosure may have following beneficial effects. In the present disclosure, the CMOS peripheral chip, the capacitor, and the interconnection pillar may be integrated into the encapsulation layer, and the photoelectric sensing through-hole may be formed in the encapsulation layer. At least the light-transmitting cover plate of the photosensitive component may be placed in the corresponding photoelectric sensing through-hole to form the interconnection structure, which may achieve the electrical connection between the CMOS peripheral chip, the capacitor, the interconnection pillar and the photoelectric sensing chip. Compared with the scheme where the photoelectric sensing chip, the CMOS peripheral chip and the capacitor are packaged on the circuit board (e.g., PCB), the present disclosure may omit the circuit board, which may not only simplify the process steps for achieving electrical connection, but also facilitate to improve packaging efficiency and to reduce the cost of electrical connection process, thereby effectively reducing the total thickness of the subsequently formed lens module.

Moreover, the photosensitive component may be made separately, and the process of integrating the CMOS peripheral chip, capacitor and interconnection pillar into the encapsulation layer may be carried out separately. Accordingly, the manufacturing process of the photosensitive component may be prevented from affecting the integration of the CMOS peripheral chip, capacitor, and interconnection pillar. Similarly, the integration of the CMOS peripheral chip, capacitor, and interconnection pillar may be prevented from affecting the photosensitive component, thereby facilitating to improve the packaging reliability and to reduce processing cost.

In addition, the photosensitive component may include the photoelectric sensing chip and the light-transmitting cover plate oppositely disposed with the photoelectric sensing chip, and the light-transmitting cover plate may be attached to the photoelectric sensing chip. The light-transmitting cover plate may prevent the subsequent packaging process from polluting the imaging region of the photoelectric sensing chip, thereby improving the imaging quality of the subsequently formed lens module.

In an optional embodiment, before placing the photosensitive component in the corresponding photoelectric sensing through-hole, the bonding structure may be formed on the encapsulation layer. Correspondingly, while placing at least the light-transmitting cover plate of the photosensitive component in the corresponding photoelectric sensing through-hole, the peripheral region of the photoelectric sensing chip may be bonded to the bonding structure. The bonding structure may be configured to achieve the physical connection of the photoelectric sensing chip and the encapsulation layer, which may further improve the bonding strength of the photoelectric sensing chip and the encapsulation layer, thereby further improving the packaging reliability.

The above detailed descriptions only illustrate certain exemplary embodiments of the present disclosure, and are not intended to limit the scope of the present disclosure. Those skilled in the art can understand the specification as whole and technical features in the various embodiments can be combined into other embodiments understandable to those persons of ordinary skill in the art. Any equivalent or modification thereof, without departing from the spirit and principle of the present disclosure, falls within the true scope of the present disclosure.

What is claimed is:

1. A packaging method of a photoelectric sensing integrated system, comprising:
forming at least one photosensitive component, wherein a photosensitive component of the at least one photosensitive component includes a photoelectric sensing chip and a light-transmitting cover plate oppositely disposed with the photoelectric sensing chip, and the light-transmitting cover plate is attached to the photoelectric sensing chip;
providing a carrier substrate;
bonding a CMOS peripheral chip, a capacitor and an interconnection pillar on the carrier substrate;
forming an encapsulation layer on the carrier substrate, wherein the encapsulation layer at least fully fills space between the CMOS peripheral chip, the capacitor, and the interconnection pillar, and at least one photoelectric sensing through-hole is formed in the encapsulation layer;
placing at least the light-transmitting cover plate of the photosensitive component in a corresponding photoelectric sensing through-hole of the at least one photoelectric sensing through-hole; and
forming an interconnection structure to provide an electrical connection between the photoelectric sensing chip and each of the CMOS peripheral chip, the capacitor and the interconnection pillar.

2. The packaging method according to claim 1, wherein forming the encapsulation layer and the at least one photoelectric sensing through-hole includes:
forming the encapsulation layer at least fully filling the space between the CMOS peripheral chip, the capacitor, and the interconnection pillar, and forming the at least one photoelectric sensing through-hole in the encapsulation layer by a photolithography process or a laser cutting method; or
bonding a prefab member on the carrier substrate to define a position and a shape of a photoelectric sensing through-hole of the at least one photoelectric sensing through-hole, forming the encapsulation layer covering the prefab member, the CMOS peripheral chip, the capacitor, and the interconnection pillar, forming an opening in the encapsulation layer, wherein the encapsulation layer exposes the prefab member, and removing the prefab member from the opening; or
bonding a prefab member on the carrier substrate to define a position and a shape of a photoelectric sensing through-hole of the at least one photoelectric sensing through-hole, forming the encapsulation layer, wherein the encapsulation layer covers the prefab member, the CMOS peripheral chip, the capacitor, and the interconnection pillar, and a top of the prefab member is at least coplanar with one of the CMOS peripheral chip, the capacitor and the interconnection pillar who has a highest top, planarizing the encapsulation layer until the prefab member is exposed, and removing the prefab member.

3. The packaging method according to claim 1, wherein:
in the photosensitive component, the photoelectric sensing chip includes a photoelectric sensing region and a peripheral region surrounding the photoelectric sensing region;
the light-transmitting cover plate is disposed in the photoelectric sensing through-hole, and the photoelectric sensing chip is disposed outside the photoelectric sensing through-hole; or both the light-transmitting cover plate and the photoelectric sensing chip are disposed in the photoelectric sensing through-hole, wherein the photoelectric sensing chip is close to an opening of the photoelectric sensing through-hole with respect to the light-transmitting cover plate;
before placing the light-transmitting cover plate of the photosensitive component in the corresponding photoelectric sensing through-hole, a bonding structure is formed on the encapsulation layer; and
placing the light-transmitting cover plate of the photosensitive component in the corresponding photoelectric sensing through-hole includes bonding the peripheral region on the bonding structure.

4. The packaging method according to claim 3, wherein:
the photoelectric sensing chip is disposed outside the photoelectric sensing through-hole, and the bonding structure is formed on the encapsulation layer outside the photoelectric sensing through-hole; or
the photoelectric sensing chip is disposed in the photoelectric sensing through-hole, the photoelectric sensing through-hole has a step, and the bonding structure is formed on the step.

5. The packaging method according to claim 1, wherein:
the photoelectric sensing chip includes a photoelectric sensing region, a peripheral region surrounding the photoelectric sensing region, and a first chip bonding pad formed in the peripheral region,
the CMOS peripheral chip includes a second chip bonding pad, and
a surface of the CMOS peripheral chip facing away from the second chip bonding pad is bonded on the carrier substrate.

6. The packaging method according to claim 5, wherein:
the first chip bonding pad faces toward the light-transmitting cover plate, and the photoelectric sensing chip is disposed outside the photoelectric sensing through-hole;
forming the interconnection structure includes: before forming the photoelectric sensing through-hole, forming a rewiring structure on a surface of the encapsulation layer facing away from the carrier substrate for electrically connecting with the second chip bonding pad, an electrode of the capacitor, and the interconnection pillar; and forming a first conductive bump on the rewiring structure, for electrically connecting with the first chip bonding pad; and
after forming the interconnection structure, along a direction from the first conductive bump to the encapsulation layer, the light-transmitting cover plate is placed in the photoelectric sensing through-hole, to make the first chip bonding pad be attached to and electrically connected with the first conductive bump.

7. The packaging method according to claim 5, wherein:
the first chip bonding pad faces away from the light-transmitting cover plate, and the photoelectric sensing chip is disposed in the photoelectric sensing through-hole;
forming the interconnection structure includes before forming the photoelectric sensing through-hole, forming a rewiring structure on a surface of the encapsulation layer facing away from the carrier substrate for electrically connecting with the second chip bonding pad, an electrode of the capacitor, and the interconnection pillar;
a first conductive bump is formed on the rewiring structure, for electrically connecting with the first chip bonding pad; and
along a direction from the first conductive bump to the encapsulation layer, after placing the photosensitive component in the photoelectric sensing through-hole, the first chip bonding pad is electrically connected with the first conductive bump by a wire bonding process.

8. The packaging method according to claim 5, wherein:
the first chip bonding pad faces toward the light-transmitting cover plate, and the photoelectric sensing chip is disposed outside the photoelectric sensing through-hole;
forming the interconnection structure includes: before forming the photoelectric sensing through-hole, forming a first rewiring structure on a surface of the encapsulation layer facing away from the carrier substrate for electrically connecting with the second chip bonding pad, an electrode of the capacitor, and the interconnection pillar; after removing the carrier substrate, forming a second rewiring structure on a surface of the encapsulation layer facing away from the first rewiring structure, for electrically connecting with the interconnection pillar; and forming a first conductive bump on the second rewiring structure, for electrically connecting with the first chip bonding pad; and
after forming the interconnection structure, along a direction from the second rewiring structure to the first rewiring structure, placing the light-transmitting cover plate in the photoelectric sensing through-hole, to make the first chip bonding pad be attached to and electrically connected with the first conductive bump.

9. The packaging method according to claim 5, wherein:
the first chip bonding pad faces away from the light-transmitting cover plate, and the photoelectric sensing chip is disposed in the photoelectric sensing through-hole;
forming the interconnection structure includes before forming the photoelectric sensing through-hole, forming a first rewiring structure on a surface of the encapsulation layer facing away from the carrier substrate for electrically connecting with the second chip bonding pad, an electrode of the capacitor, and the interconnection pillar;
after removing the carrier substrate, a second rewiring structure is formed on a surface of the encapsulation layer facing away from the first rewiring structure, for electrically connecting with the interconnection pillar;
a first conductive bump is formed on the second rewiring structure, for electrically connecting with the first chip bonding pad; and
along a direction from the second rewiring structure to the first rewiring structure, after placing the photosensitive component in the photoelectric sensing through-hole, the first chip bonding pad is electrically connected with the first conductive bump by a wire bonding process.

10. The packaging method according to claim 1, wherein:
after placing at least the light-transmitting cover plate of the photosensitive component in the corresponding photoelectric sensing through-hole, a gap is formed between a sidewall of the photoelectric sensing through-hole and the light-transmitting cover plate, wherein a width of the gap is in a range of approximately 5 μm-20 μm.

11. The packaging method according to claim 1, further including:
forming a second conductive bump at an end of the interconnection pillar facing away from the photoelectric sensing chip; and
forming a connection piece on the second conductive bump.

12. The packaging method according to claim 1, after providing the electrical connection between the photoelectric sensing chip and each of the CMOS peripheral chip, the capacitor and the interconnection pillar, further including:
forming a cover layer covering the photoelectric sensing chip over the encapsulation layer.

13. A photoelectric sensing integrated system, comprising:
a CMOS peripheral chip;
a capacitor;
an interconnection pillar;
an encapsulation layer, covering at least sidewalls of the CMOS peripheral chip, the capacitor, and the interconnection pillar and having at least one photoelectric sensing through-hole formed therein;
at least one photosensitive component, wherein a photosensitive component of the at least one photosensitive component includes a photoelectric sensing chip and a light-transmitting cover plate oppositely disposed with the photoelectric sensing chip, the light-transmitting cover plate is attached to the photoelectric sensing chip, and at least the light-transmitting cover plate of the photosensitive component is placed in a corresponding photoelectric sensing through-hole of the at least one photoelectric sensing through-hole; and
an interconnection structure, configured to provide an electrical connection between the photoelectric sensing chip with each of the CMOS peripheral chip, the capacitor and the interconnection pillar.

14. The photoelectric sensing integrated system according to claim 13, wherein:
the photoelectric sensing chip includes a photoelectric sensing region and a peripheral region surrounding the photoelectric sensing region;
the light-transmitting cover plate is disposed in the photoelectric sensing through-hole, and the photoelectric sensing chip is disposed outside the photoelectric sensing through-hole; or both the light-transmitting cover plate and the photoelectric sensing chip are disposed in the photoelectric sensing through-hole, wherein the photoelectric sensing chip is close to an opening of the photoelectric sensing through-hole with respect to the light-transmitting cover plate; and
the photoelectric sensing integrated system further includes a bonding structure formed on the encapsulation layer, for achieving bonding with the peripheral region.

15. The photoelectric sensing integrated system according to claim 14, wherein:
the photoelectric sensing chip is disposed outside the photoelectric sensing through-hole, and the bonding structure is formed on a surface of the encapsulation layer outside the photoelectric sensing through-hole; or
the photoelectric sensing chip is disposed in the photoelectric sensing through-hole, the photoelectric sensing through-hole has a step, and the bonding structure is formed on the step.

16. The photoelectric sensing integrated system according to claim 13, wherein:
the photoelectric sensing chip includes a photoelectric sensing region, a peripheral region surrounding the photoelectric sensing region, and a first chip bonding pad formed in the peripheral region, and
the CMOS peripheral chip includes a second chip bonding pad.

17. The photoelectric sensing integrated system according to claim 13, wherein:
a gap is formed between a sidewall of the photoelectric sensing through-hole and the light-transmitting cover plate, wherein a width of the gap is in a range of approximately 5 μm-20 μm.

18. The photoelectric sensing integrated system according to claim 13, further including:
a second conductive bump, formed at an end of the interconnection pillar facing away from the photoelectric sensing chip; and
a connection piece, formed on the second conductive bump.

19. The photoelectric sensing integrated system according to claim 13, further including:
a cover layer, formed over the encapsulation layer and covering the photoelectric sensing chip.

20. A lens module, comprising:
a photoelectric sensing integrated system, the photoelectric sensing integrated system including:
a CMOS peripheral chip,
a capacitor,
an interconnection pillar,
an encapsulation layer, covering at least sidewalls of the CMOS peripheral chip, the capacitor, and the interconnection pillar and having at least one photoelectric sensing through-hole formed therein,
at least one photosensitive component, wherein a photosensitive component of the at least one photosensitive component includes a photoelectric sensing chip and a light-transmitting cover plate oppositely disposed with the photoelectric sensing chip, the light-transmitting cover plate is attached to the photoelectric sensing chip, and at least the light-transmitting cover plate of the photosensitive component is placed in a corresponding photoelectric sensing through-hole of the at least one photoelectric sensing through-hole, and
an interconnection structure, configured to provide an electrical connection between the photoelectric sensing chip and each of the CMOS peripheral chip, the capacitor and the interconnection pillar; and
a lens component, electrically connected with the interconnection pillar or the interconnection structure.
